(19) United States
(12) Patent Application Publication
(10) Pub. No.: US 2026/0023892 A1
(43) Pub. Date: Jan. 22, 2026

(54) CAMPAIGN JOURNEY USER RESPONSE COMPUTER SIMULATION

(71) Applicant: Adobe Inc., San Jose, CA (US)

(72) Inventors: Harshita CHOPRA, Bangalore, IN (US); Sunav Choudhary, Bangalore, IN (US); Atanu Ranjan Sinha, Bangalore, IN (US); Sonali Arvind Surange, San Rafael, CA (US); Vasanthi Swaminathan Holtcamp, Fremont, CA (US); Sapthotharan Krishnan Nair, Santa Clara, CA (US); Zeus Orion Courtois, Austin, TX (US); Sharath Mahadev Bhat, San Jose, CA (US)

(21) Appl. No.: 18/777,311

(22) Filed: Jul. 18, 2024

(51) Int. Cl. G06F 30/20; H04L 67/306

(52) U.S. Cl. CPC G06F 30/20; G06Q 30/0201; H04L 67/306

(57) ABSTRACT

Various disclosed embodiments are directed to simulating a campaign journey, including simulating user responses at multiple touchpoints of the campaign journey. In other words, particular embodiments simulate how individuals from defined segments respond to and engage with various touchpoints of a campaign journey, which provides insights into their response behaviors and potential outcomes at each touchpoint. Based at least in part on a synthetic user profile, some embodiments simulate the campaign journey, such as simulating whether users respond to multiple touchpoints, where the prediction of a particular response at one touchpoint affects or influences the prediction of another subsequent response of a corresponding touchpoint in the campaign journey.

### BACKGROUND

Simulation technologies are computer-based tools used to mimic the operation of real-world systems or processes. Simulation technologies work by creating digital models of real-world systems or processes and then running those models to mimic the behavior of the actual systems under different conditions. These technologies are utilized across various industries for a range of purposes including training, testing, analysis, and prediction. For example, Discrete Event Simulation (DES) models the operation of systems in which events occur at discrete points in time, such as manufacturing processes, logistics, or computer networks.

Various technical challenges revolve around simulating a campaign journey. A real-world campaign journey typically follows a sequential flow, where users may progress through different stages or touchpoints over time. These touchpoints can include the presentation of content through various marketing channels such as emails, social media posts, display ads, website visits, and more at different times. At each touchpoint of the campaign journey, users may respond or interact with the campaign in different ways, such as clicking on ads, visiting a website, signing up for a newsletter, making a purchase, or completing a desired action. However, existing simulation technologies (e.g., DES) and marketing technologies fail to simulate user-level responses or interactions at touchpoints within campaign journeys, among other things. Moreover, standardized models used in these existing technologies lead to inaccurate predictions and unnecessarily consume computing resources (e.g., memory), as described in more detail below.

### SUMMARY

One or more embodiments are directed to simulating a campaign journey, including simulating user responses at multiple touchpoints of the campaign journey. In other words, particular embodiments simulate how individuals from defined segments respond to and engage with various touchpoints of a communication program (e.g., a campaign journey), which provides insights into their response behaviors and potential outcomes at each touchpoint. In operation, particular embodiments first receive computer user input. For example, the user input may include a particular touchpoint to be incorporated into the simulated campaign journey (e.g., state that the journey is to include a presentation of a specific ad). Alternatively or additionally, the user input includes a segment definition or condition representative of a target group of people.

Some embodiments generate a user profile, such as a synthetic user profile that represents an actual user profile. For example, some embodiments generate the synthetic user profile using a type of Generative Adversarial Network (GAN) (e.g., a CTGAN). The CTGAN generates synthetic profiles that mimic the distribution and characteristics of a target audience segment.

Based at least in part on the synthetic user profile and the computer user input, some embodiments then simulate a campaign journey, such as simulating whether and how users respond differently to multiple different touchpoints, where the prediction of a particular response at one touchpoint affects or influences the prediction of another subsequent response of a corresponding touchpoint in the campaign journey. For example, particular embodiments simulate that synthetic profile user “John” did not engage or otherwise interact with a promotional message at a first touchpoint, according to a first condition indicated in the user input. And particular embodiments also simulate that John did not click on an ad (e.g., ad click rate—0.004), where the ad was only transmitted to John in the simulation since he did not engage with the promotional message of the first touchpoint.

Various embodiments of the present disclosure have various technical effects and improvements over existing simulation technologies and marketing technologies. For example, some technical effects include improved simulation and prediction accuracy, improved generalization, reduced computer memory consumption, and reduced latency, among other technical effects, as described in more detail herein.

### BRIEF DESCRIPTION OF THE DRAWINGS

The patent or application file contains at least one drawing executed in color. Copies of this patent or patent application publication with color drawing(s) will be provided by the Office upon request and payment of the necessary fee. The present invention is described in detail below with reference to the attached drawing figures, wherein:

FIG. 1 is a block diagram illustrating an example computing system architecture suitable for implementing embodiments of the disclosure;

FIG. 2 is a block diagram of an example pipeline representing the inputs and outputs for simulating one or more campaign journeys, according to some embodiments;

FIG. 3 is a schematic diagram illustrating how contiguous values are binned and then mapped to a label, according to some embodiments;

FIG. 4 is a schematic diagram illustrating how a dataset is divided into “rare” and “non-rare” subsets, according to some embodiments;

FIG. 5 is a schematic diagram of a modified Conditional Tabular Generative Adversarial Network (CTGAN) for use in generating synthetic user profiles, according to some embodiments;

FIG. 6 depicts a diagram of an example neural network that is trained to generate one or more touchpoint specific user responses, according to some embodiments;

FIG. 7 is a screenshot illustrating a simulated campaign journey and estimated user interaction statistics, according to some embodiments;

FIG. 8 is a screenshot illustrating a slightly modified simulated campaign journey relative to the simulated campaign journey of FIG. 7 and estimated user interaction statistics, according to some embodiments;

FIG. 9 is a flow diagram of an example process for training one or more node specific response models, according to some embodiments;

FIG. 10 is a flow diagram of an example process for simulating a first campaign journey, according to some embodiments;

FIG. 11 is an example computer environment in which aspects of the present disclosure are employed, according to some embodiments; and

FIG. 12 is a block diagram of a computing device in which aspects of the present disclosure employ, according to some embodiments.

### DETAILED DESCRIPTION

### Overview

As described above, existing simulation technologies and marketing technologies fail to simulate campaign journeys and user-level responses or interactions because they do not account for differences in touchpoints, among other things. In various instances, there are several touchpoints (not just a one-time communication). Touchpoints themselves are heterogeneous or different from previous or subsequent touchpoints in many instances. For example, a first touch point can include an email message that is transmitted via email. And a second subsequent touchpoint can include an ad that is transmitted Short Message Service (SMS). Further, a user's response is also heterogeneous or different across touchpoints in some instances. Existing simulation technologies ignore heterogeneity. Various embodiments address this deficiency, among others, through response modeling indicative of a touchpoint specific response model.

Existing technologies, such as data-driven marketing models like Media Mix Modeling (MMM), do not account for the granular level of interactions and user responses at each stage of the campaign journey. Although they provide aggregate-level insights, they fail to capture the nuances of user behavior at individual touchpoints, leading to inaccurate predictions. Many existing communication technologies focus on single-event prediction or limited sequences of events. For example, some of these technologies simply predict whether a user will convert by purchasing a product based on the user's attributes and historical user engagement before a campaign journey. But they do not adequately simulate the complex, multi-node/touchpoint journeys that users experience in real-world marketing campaigns. What this means is that predictions will more likely be inaccurate because different touchpoints and the users' response to those touchpoints often govern or have an effect on subsequent touchpoints and user responses. For example, a user with attribute X (e.g., a certain young age group) may be more likely to convert if first presented and/or interacting with a message in a first channel (e.g., a video sharing website), followed by another message in a second channel (e.g., a text). However, absent this touchpoint or response order, the user may be unlikely to convert at all. But because existing technologies fail to account for these user responses and/or different touchpoints, they are more likely to incorrectly predict that a user will not convert.

Moreover, existing technologies are also inaccurate because that do not allow senders to include a diverse set of input variables based on their specific needs and objectives. What this means at a technical level is that a model does not capture a broad range of factors that influence campaign performance. The model cannot therefore adapt to changing environmental conditions and consumer behaviors. This also means that the model is consequently unable to capture subtle variations in user behavior and response patterns, resulting in less accurate predictions of campaign performance. This also has the consequence of not being able to tailor predictions to the specific characteristics of each user or audience segment. Therefore, the model cannot provide more personalized recommendations and insights, leading to reduced accuracy in targeting and messaging.

Moreover, datasets of existing technologies often exhibit class imbalance where certain classes or categories of outcomes are underrepresented or overrepresented relative to others. Traditional machine learning models used in existing simulation and marking technologies struggle to learn from imbalanced data, leading to inaccurate predictions. For example, if the dataset includes an age range segment that accounts for 90% of the dataset, this causes an imbalance of the model such that it is unable to generalize to minority age groups outside of the segment. Data imbalance can negatively impact the generalization ability of a machine learning model by introducing skewed representations of different classes in the training data. If a model is trained on imbalanced data, it will likely become imbalanced towards predicting the majority class and perform poorly on minority classes during inference. As a result, the accuracy of the model is inflated on the training data but significantly lower on new, unseen data, leading to poor generalization performance.

Existing technologies also unnecessarily consume computing resources. For example, these technologies are associated with unnecessary memory consumption. Marketing data is often high-dimensional and complex, comprising various types of user interactions, campaign attributes, demographic information, and behavioral data. To capture the intricate relationships and patterns within this data, machine learning models typically require a substantial amount of labeled training data to learn effectively. However, this consumes an enormous amount of computer memory.

Existing technologies are also associated with increased computing latency. Existing simulations and marking technologies often rely on real-time access to data during model inference. This means that when a prediction request is made, the model needs to retrieve the necessary data from a database or data source, preprocess it, and then make predictions. This process can introduce latency, or delays, in responding to prediction requests, especially if the data retrieval and preprocessing steps are time-consuming.

Embodiments of the present invention provide one or more technical solutions to one or more of these technical problems, as described herein. Various aspects are directed to simulating a campaign journey, including simulating user responses at multiple touchpoints of the campaign journey. In operation, particular embodiments first receive computer user input. For example, the user input may include a particular touchpoint to be incorporated into the simulated campaign journey (e.g., state that the journey is to include a presentation of a specific ad). Alternatively, the user input may include an indication (e.g., a command or user interface selection) to deactivate the particular touchpoint (or any quantity of touchpoints) from the simulation of the campaign journey. Alternatively or additionally, the user input includes a segment definition or condition representative of a target group of people. An example of a segment definition includes “Guests who live in New York and use Browser Safari.” In some embodiments, the user input additionally or alternatively includes historical user engagement/behavior data (e.g., actual customer clicks, selections, and/or queries for particular products or services on particular channels).

Some embodiments generate a user profile, such as a synthetic user profile. A “synthetic user profile” is a computer-generated user profile corresponding to a computer-generated user that does not necessarily reflect any real user that exists in the real world. Synthetic profiles can also be real profiles not available in a particular dataset, but is expected to be out there, allowing coverage of the larger distribution of profiles through simulating them. In some embodiments, the generating of the synthetic user profile is based on using a Generative Adversarial Network (GAN) (e.g., a CTGAN) that is trained to distinguish between real user profiles and fake user profiles, as described in more detail below. A useful purpose of synthetic profile generation is to be able to generate profiles with combinations of attributes which are often unavailable in data.

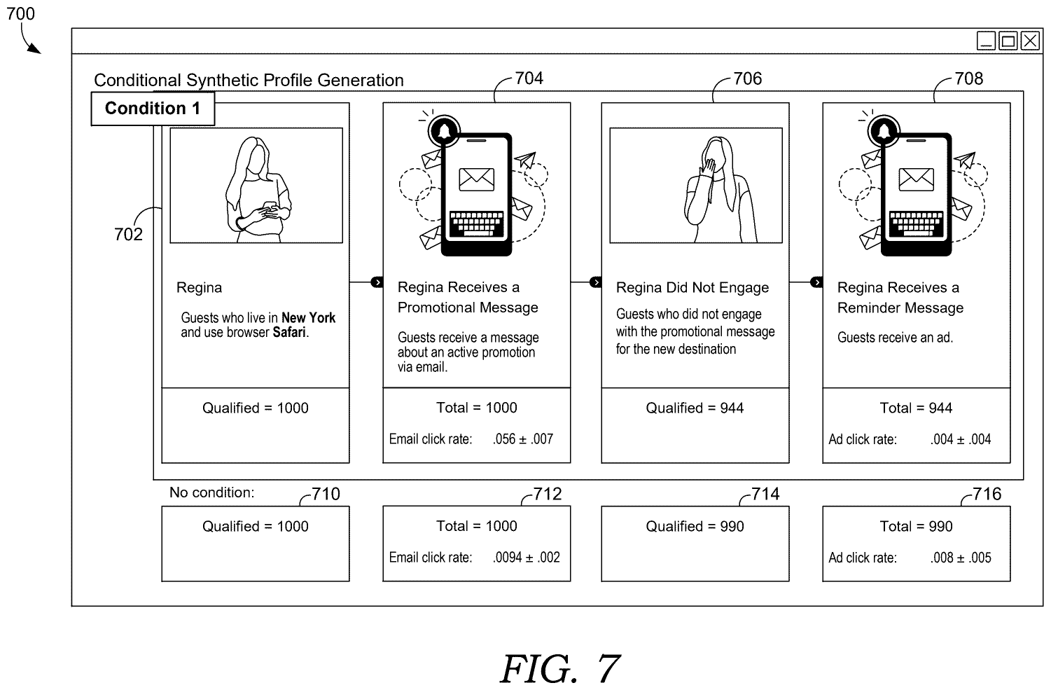

And based at least in part on the computer user input and/or the synthetic user profile, some embodiments then simulate a campaign journey, such as simulating whether users respond to multiple touchpoints, where the prediction of a particular response at one touchpoint affects or influences the prediction of another subsequent response of a corresponding touchpoint in the campaign journey. For example, as described in frame 706 of FIG. 7, particular embodiments simulate that “Regina” (and the majority of users) did not engage or otherwise interact with a promotional message at a first touchpoint, according to a first condition. And based at least part on the simulating of whether the user responded to the first touchpoint, some embodiments simulate whether the user responds to a second touchpoint of the campaign journey. For example, as illustrated in frame 708 of FIG. 7, particular embodiments simulate that Regina (and most of the other users) did not click on an ad (ad click rate −0.004), where the ad was only transmitted to Regina and other users who did not engage with the promotional message of the first touchpoint.

Various embodiments of the present disclosure have various technical effects in light of various technical solutions that overcome one or more of the problems described above. For example, one technical effect is the effect of improved prediction accuracy and simulation accuracy relative to existing simulation and marketing technologies in light of several technical solutions. Unlike MMM and other communications technologies (e.g., any technology to identify suitable receivers and send communications to them), various embodiments capture the nuances of user responses at individual touchpoints, leading to accurate predictions. Instead of focusing on a single-event prediction, various embodiments simulate the complex, multi-node/touchpoint journeys that users experience in real-world marketing campaigns. What this means is that predictions are more likely to be accurate. For example, using the illustration above, a user with attribute X (e.g., a certain young age group) may be more likely to convert if first presented and/or interacting with a message in a first channel (e.g., a video sharing website), followed by another message in a second channel (e.g., a text). Various embodiments account for these user responses and/or different touchpoints, which means that they are more likely to correctly predict whether user is likely to convert or engage in any other response depending on other touchpoints and responses in the campaign journey.

Various embodiments are also more accurate in simulation because they allow senders in communications applications to include a diverse set of input variables based on their specific needs and objectives. For example, one technical solution is receiving computer user input that includes one or more journey parameters (e.g., the inclusion or deactivation of a touchpoint) and/or a segment definitions representative of a target group of people. Consequently, a model captures a broad range of factors that influence campaign performance. By enabling senders to include a diverse set of input variables based on their specific needs and objectives, the model captures a broader range of factors that influence campaign performance. This includes demographic information, behavioral attributes, contextual data, and other relevant features that may impact user responses. Flexibility in model inputs allows for the inclusion of new data sources and features as they become available, enabling the model to adapt to changing market conditions and consumer behaviors. This adaptability ensures that the model remains relevant and effective over time, even as marketing strategies evolve. The ability to customize model inputs allows for granular analysis of user responses and campaign outcomes, leading to more nuanced predictions at each stage of the campaign journey. This granularity enables the model to capture subtle variations in user behavior and response patterns, resulting in more accurate predictions of campaign performance. Flexible model inputs facilitate the incorporation of personalized data, such as individual preferences, past interactions, and engagement history. By tailoring predictions to the specific characteristics of each user or audience segment, the model can provide more personalized recommendations and insights, leading to improved accuracy in targeting and messaging.

Various embodiments also improve the prediction accuracy and generalization of existing technologies. One technical solution is the concept of splitting a dataset into “rare” and “non-rare” categories. This refers to the process of identifying categories within the dataset that are infrequent (rare) compared to those that are more common (non-rare). Another technical solution is training or using one or more models on such categories to generate a synthetic user profile and/or predict touchpoint-level responses. For example, by distinguishing between rare and non-rare categories, various embodiments account for the distributional differences in the data and tailor model training and inference strategies accordingly. This approach helps address imbalanced datasets and ensures that the models generalize well to both minority and majority classes. This means that the models will not become imbalanced towards predicting the majority class and perform poorly on minority classes during inference because the models take into consideration rare and non-rare categories. As a result, the model is accurate not only on the training data but also on new, unseen data, leading to better generalization performance.

Another technical effect of various embodiments is reduced computer memory consumption. One technical solution to reduce memory consumption is the generation of synthetic user profiles. Instead of relying solely on real-world data (e.g., real user profiles) for model training and inference, the invention generates synthetic profiles on-demand (e.g., using Conditional Tabular Generative Adversarial Networks (CTGANs)). These synthetic profiles closely resemble real data but are generated algorithmically, without the need to store large volumes of raw data in memory. Real data takes up a lot of storage. Various embodiments, however, store only model parameters, which take up less storage. In various aspects, synthetic profiles are generated dynamically as needed, rather than storing a fixed dataset in memory. This on-demand generation approach minimizes the amount of data that needs to be stored in memory at any given time, reducing memory consumption. By using synthetic profiles for model training and inference, various embodiments eliminate the need for real-time access to large datasets during prediction. This removes the burden of storing and managing massive datasets in memory, further reducing memory footprint. Moreover, a core innovation of CTGANs lies in their ability to learn from limited training data effectively. Traditional machine learning models may require large volumes of labeled training data to achieve satisfactory performance. However, CTGANs can generate synthetic data that closely resembles the distribution of the training data, even when the training dataset is relatively small. This means that there is less training data required in memory, thereby improving memory consumption. Further, since synthetic profiles can be generated on-the-fly, the various embodiments can scale to accommodate varying data sizes and computational resources. This scalability ensures that memory consumption remains manageable even as the dataset grows or as computational demands increase.

Another technical effect is reduced computing latency. In some embodiments, instead of relying on real-time data retrieval during model inference, one technical solution is the access or generation of synthetic user profiles (e.g., on-demand using CTGANs). These synthetic profiles closely resemble real user data but are generated algorithmically. By eliminating the need for live data retrieval, various embodiments reduce the latency associated with fetching large datasets over a network. Before communication over a network, data often requires preprocessing to ensure compatibility and efficiency. If real user profiles were accessed in real-time, for example, a model would first have to preprocess (e.g., convert strings to vectors and decode packet data) the data before analyzing it. For example, the platform collects real user profile data in HTML format but requires the data to be in JSON format so must convert the data in near real-time, thereby increasing network latency. Various embodiments minimize such preprocessing required by generating synthetic user profiles that are already pre-processed, structured, and formatted for model inference. For example, using the illustration above, the data is already in a particular format, such as JSON. This reduces the compute latency and needed to prepare data for communication. Further, in some embodiments, the synthetic user profiles are designed to capture the essential characteristics of the original dataset while requiring less storage space. This efficiency extends to data transmission, as synthetic user profiles can be communicated with less latency and efficiently compared to raw data (e.g., which may have lots of unnecessary information about a real user). By transmitting compact representations of data, various embodiments reduces the latency and bandwidth required for communication.

### Example System

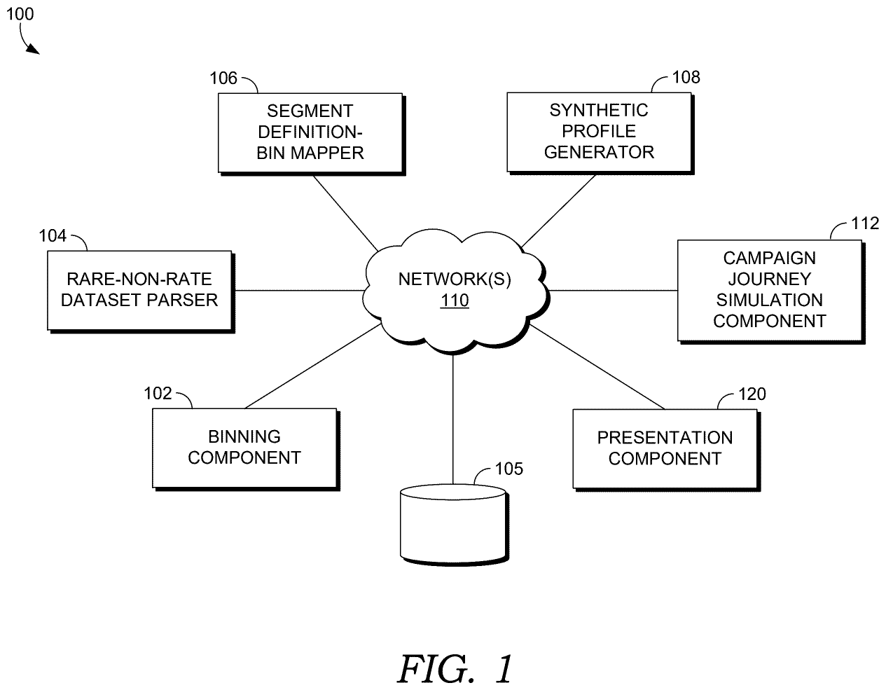

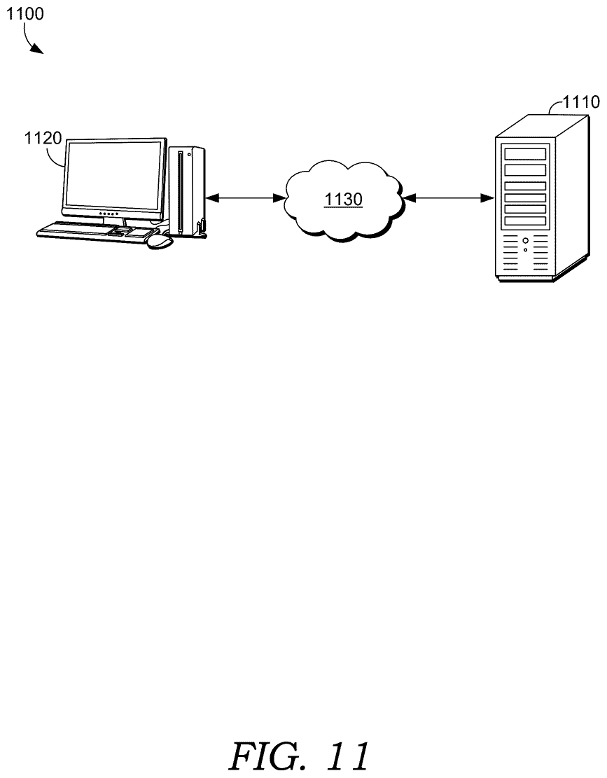

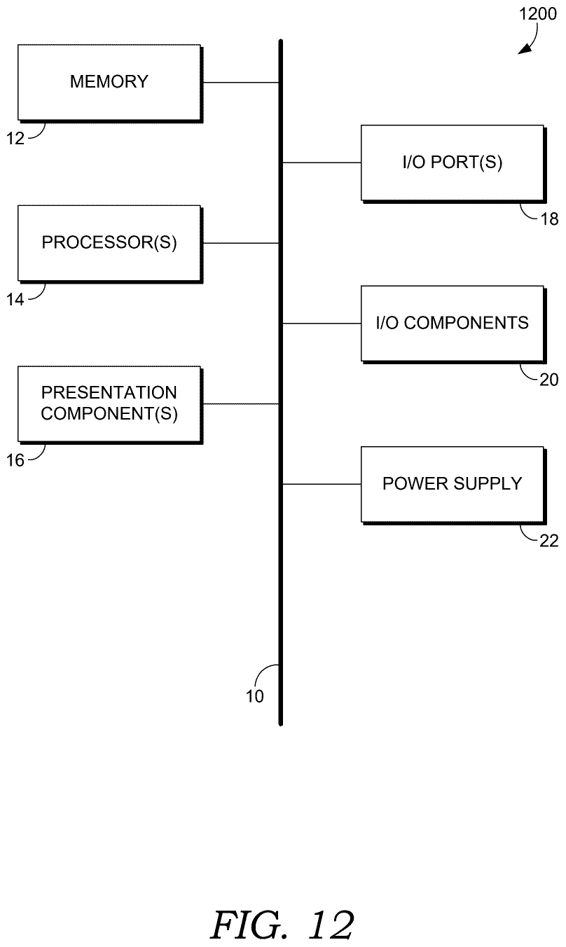

Referring now to FIG. 1, a block diagram is provided showing aspects of an example computing system architecture suitable for implementing an embodiment of the disclosure and designated generally as the system 200, according to some embodiments. The system 200 represents only one example of a suitable computing system architecture. Other arrangements and elements can be used in addition to or instead of those shown, and some elements may be omitted altogether for the sake of clarity. Further, many of the elements described herein are functional entities that may be implemented as discrete or distributed components or in conjunction with other components, and in any suitable combination and location. For example, some or each of the components of the system may be located within a single computing device (e.g., the computing device 1200 of FIG. 12). Alternatively, some or each of the components may be distributed among various computing devices, such as in a distributed cloud computing environment. In some embodiments, the system 100 and each of the components are located within the server and/or user device of FIG. 11, as described in more detail herein.

The system 100 includes network(s) 110, which is described in connection to FIG. 11, and which communicatively couples components of system 100, including a binning component 102, a rare-non-rate dataset parser 104, a segment definition—bin mapper 106, a synthetic profile generator 108, a campaign journey simulation component 112, a presentation component 120, and storage 105. The components of the system 100 may be embodied as a set of compiled computer instructions or functions, program modules, computer software services, logic gates, hardware accelerators, or an arrangement of processes carried out on one or more computer systems. The system 100 generally operates to simulate a campaign journey of multiple touchpoints.

The binning component 102 is generally responsible for binning numerical values in a dataset (e.g., stored to the storage 105). Binning enables the transformation of continuous numerical data of the dataset into categorical representations, which can be used for further analysis, model training, or simulation purposes in the context of marketing campaign optimization and predictive analysis. In some embodiments, such dataset includes interaction/user engagement events (e.g., sign-ups, email clicks, ad views, app downloads and launches, site visits, and social media redirections), or touchpoints, between users and various services, including campaign data and marketing data. The dataset in some embodiments includes target response labels used for demonstrating concepts, such as Email Click (indicating whether an email was clicked) and Display Click (indicating whether a display ad was clicked). Additionally, in some embodiments, the dataset (or another dataset) includes the Conversion label, indicating whether users subscribed to a product.

For each user profile, the dataset includes static attributes (such as geographic location, operating system, and browser) and aggregate-level features generated from event data. These attributes capture user behavior over a time (e.g., four-week) period and are curated empirically, incorporating both static and time-stamped information.

The rare-non-rare dataset parser 104 is generally responsible for parsing or splitting the dataset into rare and non-rare categories. The distinction between “rare” and “non-rare” categories refers to the frequency of occurrence of certain categorical variables within the dataset. In some embodiments, the “rare” categories data is subset of the dataset that comprises rows (e.g., users) containing at least one rare category (e.g., a column/attribute). In some embodiments, the “non-rare” categories data refers to a subset that contains rows with only non-rare categories, where each variable for a row must be non-rare according to a strict definition.

Consider the following example, a dataset containing information about user interactions with marketing campaigns, including attributes such as geographic region, browser type, and referral source. One of the categorical variables is “Referral Source,” with values such as “Direct,” “Organic Search,” “Social Media,” and “Paid Advertisement.” With respect to rare categories data, this subset might include rows where the referral source is a less common channel, such as “Referral Link from Partner Website” or “Email Forwarding from Newsletter.” With respect to non-rare categories data, this subset might include rows where the referral source is a more common channel, such as “Direct,” “Organic Search,” or “Social Media.” By splitting the dataset into rare and non-rare categories, various embodiments allow for tailored modeling strategies to address the distributional differences in the data and ensure that models generalize well to both rare and non-rare categories, thereby improving predictive accuracy and performance in marketing campaign optimization and analytics

The segment definition-bin mapper 106 is generally responsible for mapping one or more segment definitions (e.g., provided by a user) to one or more bins generated by the binning component 102. That is, given a segment definition, represented as conditions on attributes present in the dataset, some embodiments convert the continuous values of numerical attributes indicated in the segment definition to corresponding bins (e.g., via a mapping dictionary). A “segment definition” refers to the set of characteristics and attributes that define a specific group or segment of users within a larger dataset. These characteristics may include, for example, demographic information, behavioral attributes, and other relevant features that distinguish one segment from another. Segment definitions are used to target specific audiences for marketing campaigns and analyze their behavior and response patterns.

For example, consider a segment definition based on user engagement with email marketing campaigns. The segment targets users who have previously interacted with promotional emails and are likely to respond positively to future email campaigns. For example, the segment definition may include the following criteria: Email Engagement (Users who have opened at least three promotional emails in the past month), Geographic Location (Users located in the United States), Device Type (users who primarily use mobile devices for email access), and Purchase History (users who have made a purchase through email promotions in the past six months).

Once the segment definition is established, various embodiments map the definition to corresponding bins to facilitate the simulation process. This mapping involves converting the continuous values of numerical attributes in the segment definition to predefined bins or categories. For example, using the “Email Engagement” criterion indicated above, which specifies users who have opened at least three promotional emails in the past month, to map this criterion to bins, various embodiments may define bins based on the frequency of email opens as follows. Bin 1: Users who opened 0-2 promotional emails in the past month. Bin 2: Users who opened 3-5 promotional emails in the past month. Bin 3: Users who opened 6 or more promotional emails in the past month. Once the segment definition is mapped to bins for all relevant attributes, it provides a structured representation of the target audience, which can be used to generate synthetic profiles and simulate user responses for marketing campaign optimization and decision-making.

The synthetic profile generator 108 is generally responsible for generating one or more synthetic user profiles based on taking, as input, the output of the binning component 102, the rare-non-rare dataset parser 104, and the segment definition mapper 106. For example, the segment definition may be as follows: Age: 25-35 years, Gender: Female, Location: Urban areas, Previous Purchase History: Bought similar products in the last 6 months. The numerical attributes like age could be binned into categories like “25-29 years” and “30-35 years”. Location could be binned into categories like “Urban” and “Suburban”. Each attribute value in the segment definition is mapped to the corresponding bin label based on the binning process. For example: Age: “25-35 years”→Bin label “25-29 years”, “Urban”→Bin label “Urban”.

The CTGAN model, for example, trained on the dataset with similar segment definitions, is used to generate synthetic profiles conditioned on the mapped attribute-values. The CTGAN model takes the mapped attribute-values as input and generates synthetic profiles that mimic the distribution and characteristics of the target audience segment. For instance, it may generate synthetic profiles of individuals aged 25-29 years, female, residing in urban areas, and with a history of purchasing similar products. The generated synthetic profiles represent individuals who match the specified segment definition. These profiles can be used for simulating the audience's response to marketing campaigns, predicting engagement with ads or emails, and evaluating the effectiveness of different strategies tailored to this audience segment. In this way, the CTGAN synthesizes realistic user profiles based on the segment definition provided, capturing the nuances and patterns observed in the original dataset to generate representative profiles for targeted marketing analysis.

In some embodiments, the CTGAN adapts its generation process based on whether the segment definition includes rare or non-rare categories, ensuring that the synthetic profiles accurately reflect the distributional differences in the data and produce realistic representations of the target audience for marketing analysis, as described in more detail below.

The campaign journey simulation component 112 is generally responsible for simulating one or more campaign journeys based at least in part on taking the synthetic user profile(s) (generated by the synthetic profile generator 108) and/or a journey map as input. A “journey map,” as described herein, refers to a visual representation or outline of the sequence of touchpoints/events encountered by users within a specific segment as they interact with a product, service, or platform. This map illustrates the various stages or steps in the user's journey, including responses or interactions with marketing campaigns, advertisements, emails, website visits, app downloads, and other relevant activities.

Consider, for example, a scenario where a marketing team wants to simulate the performance of a campaign journey targeting users interested in a new product launch. The campaign journey includes touchpoints such as email promotions, social media ads, and website visits. The marketing team provides a predefined journey map outlining the sequence of touchpoints and events for the campaign. They also specify the segment definition—characteristics and attributes of the target audience segment, such as demographics, interests, and past behaviors. Based on the segment definition, the CTGAN (Conditional Tabular Generative Adversarial Network) generates synthetic user profiles that represent the target audience. These profiles are created by sampling from the CTGAN model conditioned on the attribute-values derived from the segment definition.

For each touchpoint in the journey map (e.g., email promotion, social media ad), node type-specific response models are employed in some embodiments. In some embodiments, separate models are trained and used for inference for different types of touchpoints. These models take synthetic user profiles as input and predict the likelihood of user response (e.g., email click, ad click) at each touchpoint. The journey with nodes is parsed, and the node-specific response model is executed for each touchpoint. For example, the response model for email promotions predicts the probability of users clicking on the email, while the response model for social media ads predicts the likelihood of users clicking on the ad.

These predictions are made for each synthetic user profile generated, simulating the response of the target audience to each touchpoint. The simulation results provide insights into the expected user responses and engagement levels at each touchpoint of the campaign journey. Senders can analyze the predicted outcomes, identify potential bottlenecks or opportunities for optimization, and make data-driven decisions to refine their marketing strategies. By simulating the campaign journey and user responses using synthetic user profiles and node type-specific response models, senders can gain valuable insights into the effectiveness of their campaigns, optimize resource allocation, and improve overall campaign performance.

The presentation component 120 is generally responsible for causing presentation of one or more elements, such as a user interface, one or more campaign journeys, one or more synthetic user profiles, and/or simulations of user responses and/or touchpoints, at a user device. In some embodiments, such presentation is in the form of a user interface. Such user interface may be a graphical user interface (GUI), and/or a natural user interface (NUI) that processes air gestures, voice, or other physiological inputs generated by a user. In some instance, inputs may be transmitted to an appropriate network element for further processing. A NUI may implement any combination of speech recognition, touch and stylus recognition, facial recognition, biometric recognition, gesture recognition both on screen and adjacent to the screen, air gestures, head and eye tracking, and touch recognition associated with displays on a user device.

Based on content logic, device features, associated logical hubs, inferred logical location of the user, and/or other user data, presentation component 120 may determine on which user device(s) content is presented, as well as the context of the presentation, such as how (or in what format and how much content, which can be dependent on the user device or context) it is presented and/or when it is presented. In some embodiments, the presentation component 120 generates user interface features. Such features can include interface elements (such as graphics buttons, sliders, menus, audio prompts, alerts, alarms, vibrations, pop-up windows, notification-bar or status-bar items, in-app notifications, bubble data objects, or other similar features for interfacing with a user), queries, and prompts.

Storage 105 generally stores information including data (e.g., datasets, synthetic user profiles, and campaign journey maps), computer instructions (for example, software program instructions, routines, or services), data structures, and/or models used in embodiments of the technologies described herein. In some embodiments, storage 105 represents any suitable data repository or device, such as a database, a data warehouse, RAM, cache, disk, RAID, and/or a storage network (e.g., Storage Area Network (SAN)).

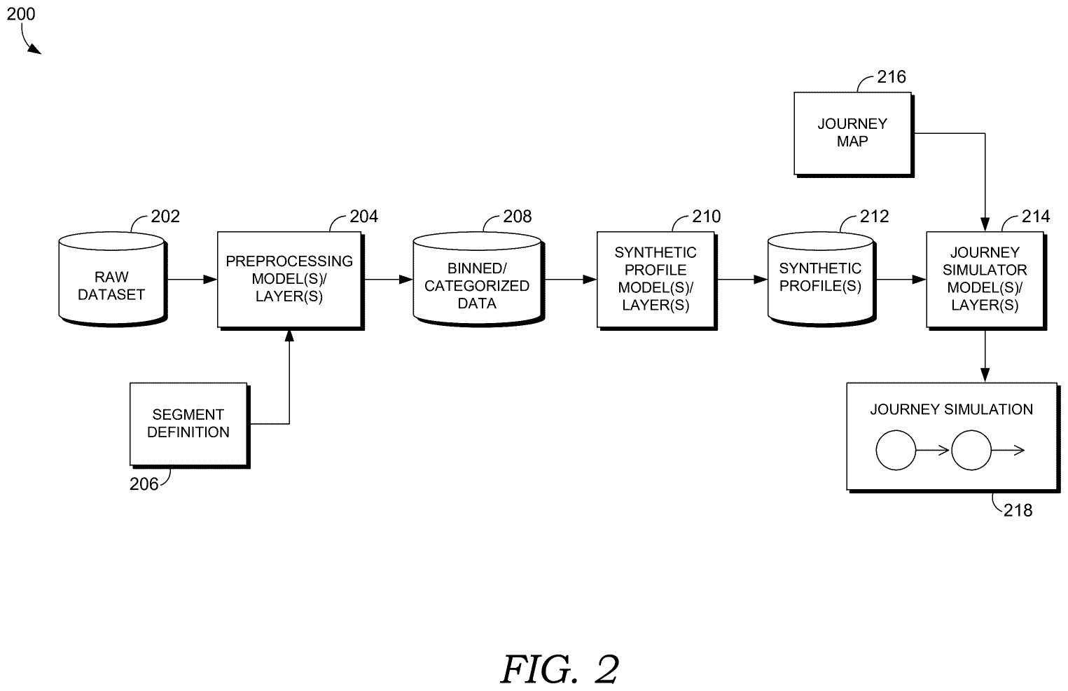

FIG. 2 is a block diagram of an example pipeline 200 representing the inputs and outputs for simulating one or more campaign journeys, according to some embodiments. In some embodiments, each of the components 204, 210, and 214 represent a respective model (e.g., such that the pipeline 200 includes an ensemble machine learning models) or, alternatively, layers of a single model. For example, in some embodiments, each of the components 204, 210, and 214 together are all layers (e.g., input, intermediate, and output layers) of a single model. In some embodiments, the preprocessing model(s)/layer(s) 204 represents or includes the binning component 102 and/or the rare-non-rare dataset parser 104 of FIG. 1. In some embodiments, the synthetic profile model(s)/layer(s) 210 represent or include the synthetic profile generator 108 of FIG. 1. In some embodiments, the campaign journey simulator model(s)/layer(s) 214 includes or represents the campaign simulation component 112 of FIG. 1.

At a first time, the preprocessing model(s)/layer(s) 204 extracts data from the raw dataset 202 (e.g., the dataset described in FIG. 1) and preprocesses the dataset 202. For example, as described with respect to FIG. 1, particular embodiments bin numerical values and parse the data into rare and non-rare categories. As illustrated in the pipeline 200, the preprocessing model(s)/layer(s) 304 also receives (e.g., from a user and/or automatically from a segment definition generator) a segment definition and responsively preprocesses such segment definition. Preprocessing may additionally or alternatively include any other types of preprocessing, such as data cleaning, data transformation (e.g., converting categorical variables into numerical representations, such as one-hot encoding or label encoding), feature engineering, dimensionality reduction, data normalization, text preprocessing (e.g., tokenizing words).

In some embodiments, the raw dataset 202 includes real user interaction data (e.g., real click events from real users of a platform). For example, in some embodiments the raw dataset 202 includes as marketing campaign dataset, which contains interaction events on particular touchpoints (touchpoints) between users and several services including campaign data and marketing data. In some embodiments, this raw dataset contains timestamped information about user sign-ups, email clicks, ad views, app downloads and launches, site visits and redirection from social media campaigns. For example, such timestamped information can include a time at which a user clicked an email. In some embodiments, there are two subsets of data within the raw dataset 202 where the first subset includes Email clicks (a quantity and/or indication of whether one or more emails are clicked), and Display clicks (a quantity and/or indication of whether one or more display ads are clicked), both of which correspond to node specific response “email click” model and “ad” models, as described in more detail below. In some embodiments, the second subset includes an additional target label—Conversion—in a separate time period, where users converted (subscribed to a product) for a particular time period.

In some embodiments, the raw dataset 202 includes static attributes of one or more users and/or user devices. Examples of the static attributes include region or “geo” (the geographic region or location associated with the user), OS (the operating system used by the user's device (e.g., Windows, macOS, IOS, Android)), browser (the web browser used by the user (e.g., Chrome, Firefox, Safari, Internet Explorer)).

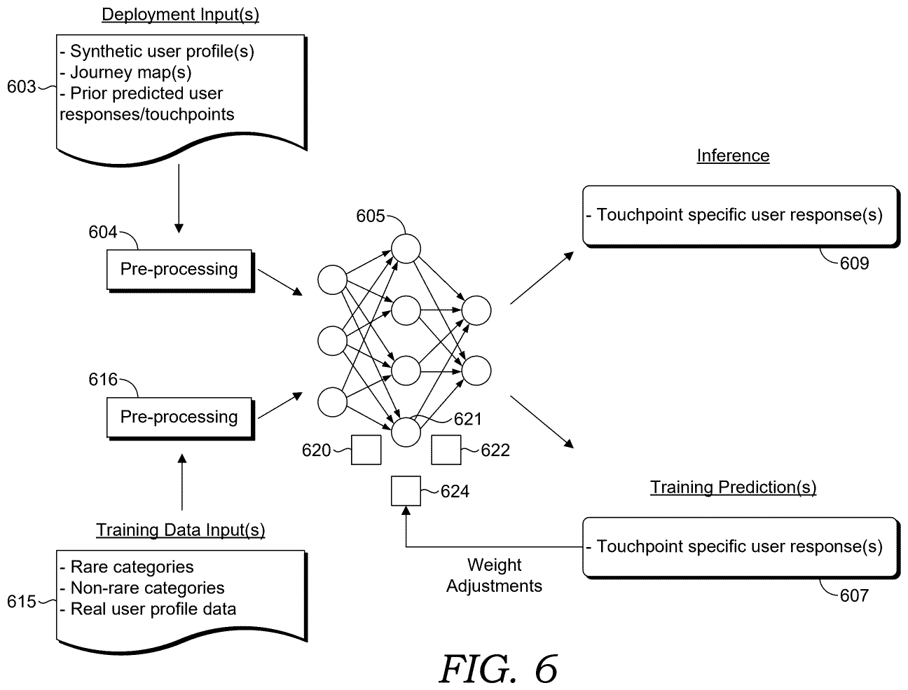

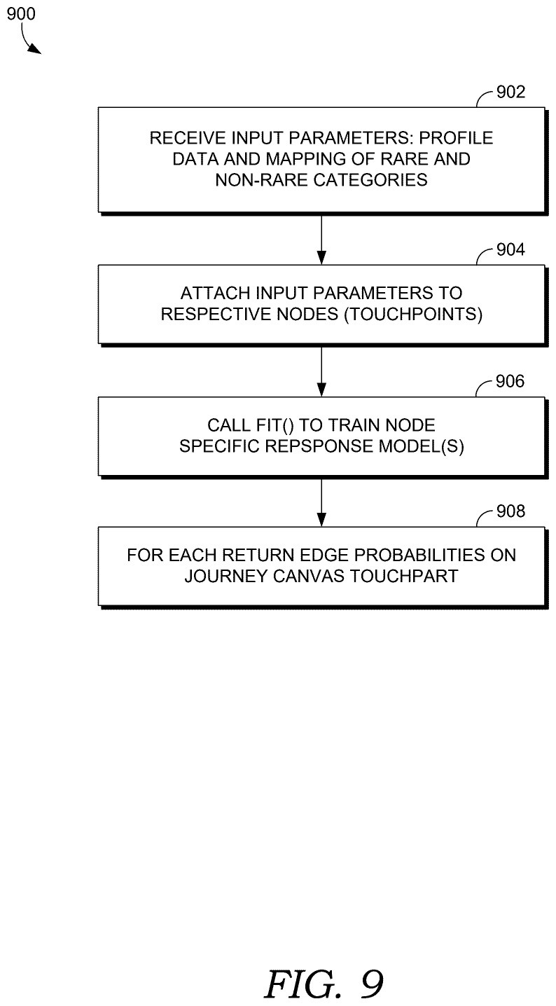

In some embodiments, the raw dataset 202 additionally or alternatively includes dynamic attributes generated from user interaction/engagement/behavior data. For example, in some embodiments, the dataset 202 presents the overall behavior (including clicks and purchases) of one or more real users over 4 weeks while interacting with various events or touchpoints. For example, the dataset 202 in some examples captures a number of times emails were opened in a time period (frequency) by user(s). In some embodiments, a total of 14 attributes are curated. In an illustrative example of such dynamic attributes, they may include: quantity of emails sent by the user(s), quantity of emails opened by the user(s), email clicks (whether the user(s) clicked on any links within the email), bounce number (the number of emails that bounced, meaning they were not successfully delivered to the recipient's inbox), open probability (the probability that an email sent to the user(s) will be opened, click probability (the probability that the user(s) will click on a link within an email they have opened), ad click (represents whether the user(s) clicked on an advertisement), paid search clicks (represents the number of clicks originating from paid search campaigns), organic search clicks (represents the number of clicks originating from organic (non-paid) search results), social visits (represents the number of visits or interactions from social media platforms, conversion (represents whether the user(s) completed a desired action or goal, such as making a purchase or filling out a form). These static and dynamic attributes are used for model training, as described with respect to the modified GAN 500 of FIG. 6, the neural network 605 of FIG. 6, and/or the process 900 of FIG. 9. This attribute set comprises mixed-data—numerical (e.g., emailOpen num) and categorical variables (e.g., region)—as is customary in the dataset of any customer-org, and thus serves as a good representative of the types of data used.

The output of the preprocessing model(s)/layer(s) 204 is the binned and/or categorized (e.g., “rare” versus “non-rare”) data, and/or any other preprocessed data. The synthetic profile model(s)/layer(s) 210 then takes, as input, the binned/categorized data 208 in order to generate one or more synthetic profiles 212, taking into account the segment definition 206. The segment definition 206 outlines the conditions and/or attributes of a particular segment (representative of a particular human group), such as demographic information, behavioral attributes (e.g., user engagement click range), and/or other relevant features. \

Responsively, the campaign journey simulator model(s)/layer(s) 214 takes, as input, the synthetic profile(s) 212 and a journey map 216 in order to produce the campaign journey simulation 216. The journey map 216 represents the sequence of touchpoints and/or events encountered by users within the segment definition as they are presented with and/or interact with a product, service, or platform. In some embodiments, the journey map 216 is provided by a user (e.g., a receiver of a sender message). In alternative embodiments, one or more touchpoints of the journey map are predicted, recommended to users, or otherwise automatically provided to the campaign journey simulator model(s)/layer(s) 214. For example, given the raw dataset 202 (which includes historical user conversions, clicks, touchpoints, and/or other attributes), various embodiments can predict or generate a score indicative of a sequence of successive touchpoints that a campaign journey should include.

For example, a machine learning model may be trained to learn patterns and associations between particular segment definitions, user profiles, journeys, touchpoints, user responses to those touchpoints, and combinations of these features to predict that given a first touchpoint, a next touchpoint should be presented next in the journey map based on the user response success in the training data. For example, an optimization algorithm (e.g., Gradient Descent) may be used to adjust weights and biases during training based on locating a pattern that given segment 1, successive touchpoints A and B, and subsequent response or conversion C (indicating conversion). Accordingly, at runtime, for example, if a user fits in segment 1, various embodiments would recommend or present touchpoints A and B in the campaign journey map or campaign journey simulation.

In some embodiments, the journey simulator model(s)/layer(s) 214 represent multiple node type-specific response models to simulate user responses at each touchpoint within the campaign journey. This leverages the attributes present in the synthetic profiles generated for the defined segment to predict user response at different touchpoints. Separate models are trained for distinct node/touchpoint types, such as email click prediction and ad click prediction, to cater to the specific characteristics of each touchpoint. For example, a first machine learning model may be trained to only predict the email click rate of users based on training on historical email click rates of users. And a second machine learning model may be trained to only predict the ad click rate of users based on training on historical ad click rates of users.

In some embodiments, for every node/touchpoint type, given the segment definition, multiple models represented by the journey simulator model(s)/layer(s) are trained and used for inference for rare and non-rare categories to account for the distributional differences in the data. For example, a first machine learning model may be a “Rare Category Model,” which is trained exclusively on profiles containing rare categories data. A second machine learning model may be a “Non-Rare Category Model,” which is trained on profiles devoid of rare categories data. Once trained, these models are used for evaluation on synthetic profiles generated for the defined segment according to the segment definition. By employing separate models for rare and non-rare categories, various embodiments ensure that the response predictions accurately reflect the distributional characteristics and behaviors associated with each category type.

### Example Data Structures

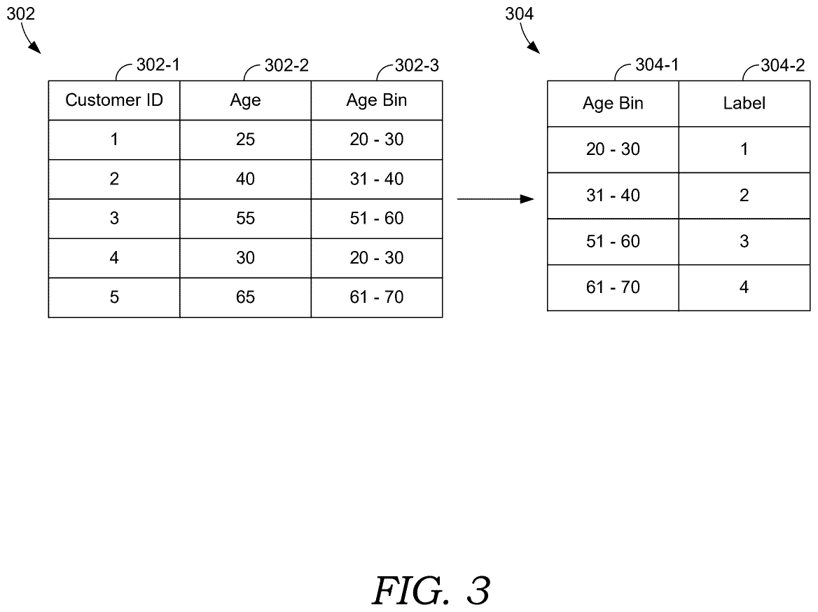

FIG. 3 is a schematic diagram illustrating how contiguous values are binned and then mapped to a label, according to some embodiments. FIG. 3 includes two data structures 302 and 304 (e.g., a lookup table). In some embodiments, the data structures 302 and 304 represents what is generated or populated by the binning component 102 of FIG. 1. “Binning” refers to the process of dividing a continuous variable into discrete intervals or bins. This technique may be used to simplify data analysis and modeling, particularly when dealing with large datasets or when specific patterns are more apparent in grouped data than in individual data points.

With respect to FIG. 3, there is an original dataset (corresponding to columns 302-1 and 302-2) containing information about customer ages. The ages range from 18 to 80 years old. To perform binning, various embodiments divide this range into several intervals or bins, as illustrated by the column 302-3. In this example, ages have been grouped into bins such as “20-30”, “31-40”, “51-60”, etc. Each customer's age is now represented by the bin to which it belongs rather than the exact age. Binning helps in simplifying the analysis of age-related patterns and trends, especially when dealing with large datasets. Binning plays a role in preprocessing and organizing the data before training models or generating synthetic user profiles.

Given a segment definition, represented as conditions on attributes present in data, some embodiments convert the continuous values of numerical attributes to corresponding bins using a Mapping Dictionary (e.g., dataset 302 of FIG. 3). For example, if the segment definition is [geo=New York, productViews less than 10, productPurchased between 1 and 10], various embodiments will productViews to corresponding bins, computing the following as the final condition for CTGAN based on the categorized values: [geo=[New York], productViews=[12, 13, 14, 15], productPurchased=[10,11]]. Here, [12, 13, 14, 15] are the bin labels that cover the values of productViews>10, and [10,11] are the bin labels that cover the values of productPurchased between 1 and 10.

In various embodiments binning includes various functionality as described below. Various embodiments first identify numerical columns within the original dataset. Numerical columns are then binned based on quantiles ranging, for example, from 0.1 to 0.9. This approach ensures that the bins have varying widths for each column, accommodating the distribution characteristics of individual features. Each bin is then labeled by order, starting from 10, for example. Labeling in this manner establishes a systematic representation of the bins for easy referencing during subsequent processes. In some embodiments null values within the numerical columns are replaced with a predefined value, such as −10. This ensures consistency in the data and prevents any disruption in the binning process.

In various embodiments, a dictionary, such as 304, is maintained to map the assigned labels to their corresponding bin ranges or vice versa. This dictionary serves as a reference for understanding the mapping between categorical labels and their respective numerical ranges, facilitating processing given a segment definition. For example, if the data structure 304 represents a lookup table, the keys may be the age bins and the lookup values may be the corresponding labels, such that the data structure 304 includes corresponding key-value pairs (e.g., age bin 20-3, as a key, is mapped to label 1).

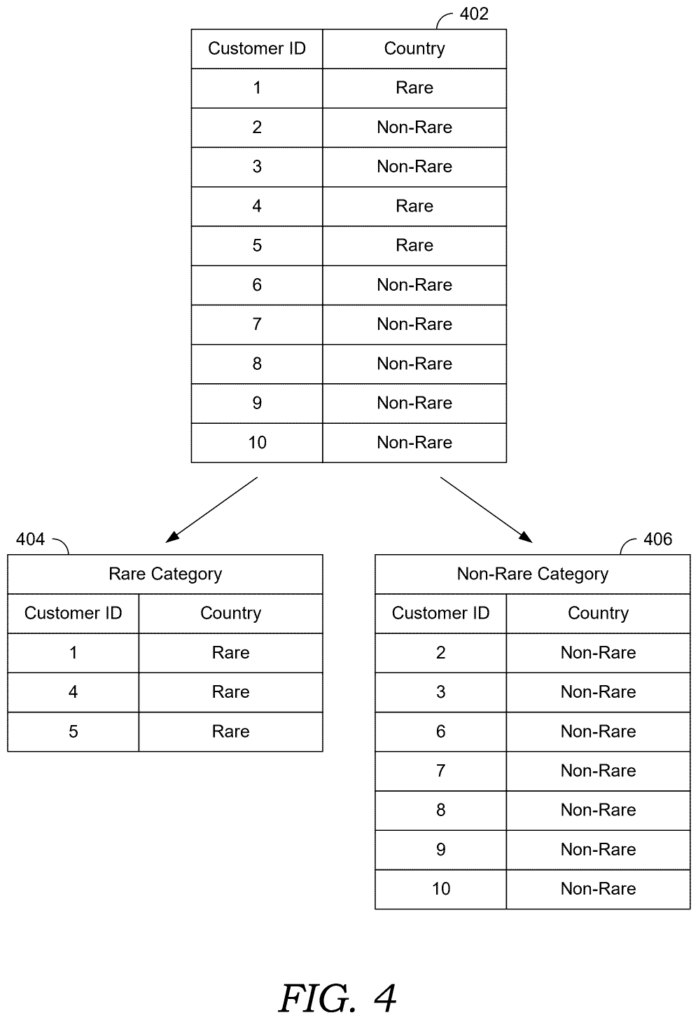

FIG. 4 is a schematic diagram illustrating how a dataset is divided into “rare” and “non-rare” subsets, according to some embodiments. FIG. 4 includes an original dataset 402, which is then parsed into subsets of rare category 404 (e.g., a first data structure) and a non-rare category 406 (e.g., a second data structure). In some embodiments, the rare-non-rare dataset parser 104 of FIG. 1 is the component responsible for generating the subsets of rare and non-rare categories 404 and 406. As illustrated in FIG. 4, the rare and non-rare categories are divided based on what countries users reside in. Some countries are rarely represented in data of a US site while others like US well represented (i.e., are non-rare).

As described herein, some categories constitute a small portion of the dataset, while others are more prevalent. Traditional models struggle to effectively learn from rare categories due to this disparity. Imbalance introduced by rare categories can lead to imbalanced models and reduced predictive accuracy. Standard modeling techniques may fail to generalize well to rare categories, impacting overall model performance. The dataset 402 is divided into two subsets 404 and 406 to manage the presence of rare categories effectively. In some embodiments, “rare” categories comprise rows with at least one rare category. In some embodiments, “non-rare” categories contains rows with only non-rare categories (e.g., every column or attribute contains non-rare values). Some embodiments thus use a strict definition of non-rare categories, whereby each variable for a row must be non-rare.

In some embodiments, a user can select her definition of rare versus non-rare categories on a UI. Alternatively or additionally, some embodiments automatically define rare versus non-rare based on programming rules and thresholds. For example, a user may provide a command (and/or a programming statement may specify) to tag a row or user data as “rare” if the purchase frequency is greater than 10 or any other purchase frequency threshold. In an illustrative example, original dataset for customer ID 1 may include an actual purchasing frequency of 11-under the purchase frequency column. Responsively, based on a programming statement that specifies the 10 threshold, some embodiments then change and/or supplement the “11” value to “Rare” (as illustrated in the dataset 402) under the purchase frequency based on 11 exceeding the 10 threshold.

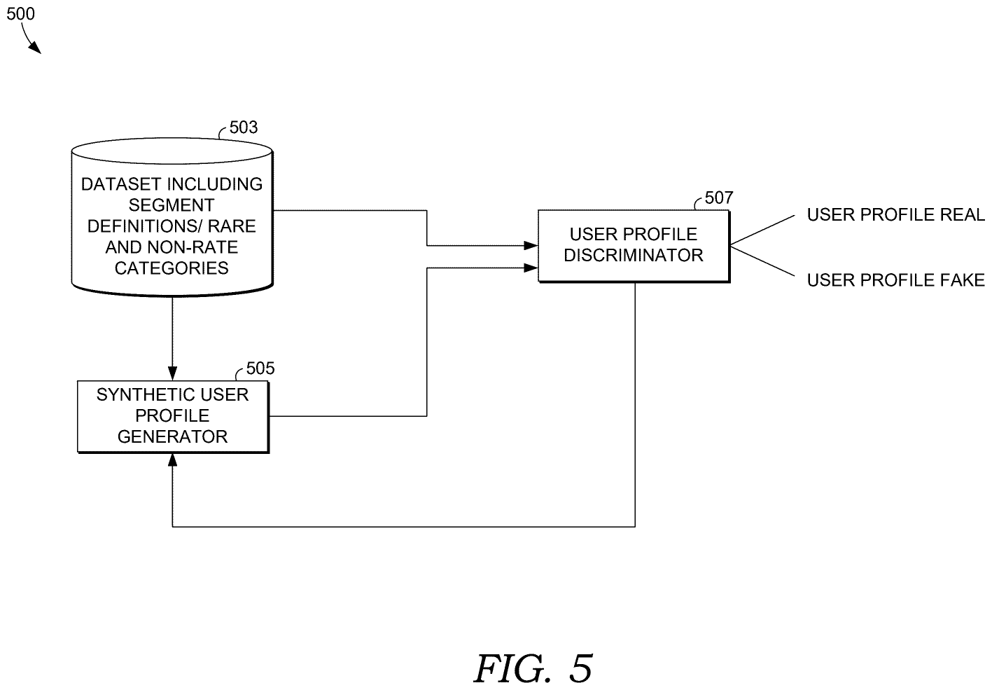

FIG. 5 is a schematic diagram of a modified Conditional Tabular Generative Adversarial Network (CTGAN) 500 for use in generating synthetic user profiles, according to some embodiments. The modified GAN 500 includes a set of neural networks—the synthetic user profile generator 505 (a first neural network) and the user profile discriminator 507 (a second neural network)—and a dataset 503 that includes one or more segment definitions, and rare and non-rare categories (e.g., as parsed and described in FIG. 4). In some embodiments, the dataset 503 represents a preprocessed form of the raw dataset 202 of FIG. 2. In some embodiments, the synthetic profile generator 108 uses or represents the modified CTGAN 500. Through iterative training, CTGAN 500 learns the underlying data distribution (e.g., the quantity of clicks of various real users for specific touchpoints), enabling it to generate high-fidelity synthetic user profiles that closely resembles the original dataset's (e.g., raw dataset 202 of FIG. 2) statistical properties.

CTGAN is a type of generative model specifically designed to generate synthetic tabular data conditioned on certain input conditions or contexts. Tabular data refers to structured data organized in rows and columns, where each row represents an individual sample or observation (e.g., particular synthetic users), and each column represents a feature or attribute of that sample (e.g., marketing data, such as clicks, views, demographic location, age, etc.). Examples of tabular data include spreadsheets, databases, or CSV files, where each row corresponds to a data record and each column represents a specific attribute or characteristic of the data.

Once a segment definition (e.g., segment definition 206) is mapped to corresponding bins (e.g., as described with respect to FIG. 3), trained CTGAN models 500 are used for conditional profile generation in some embodiments. Some embodiments first perform conditional sampling where profiles are generated from the CTGAN models conditioned on the attribute-values derived from the segment definition in 503. Depending on whether the segment contains rare categories or not, the appropriate CTGAN model 500 is selected for sampling in some embodiments. In some embodiments, if the segment definition contains rare categories, the first CTGAN model 500 trained on rare categories data is utilized for sampling. This ensures that the generated profiles accurately reflect the distribution and characteristics of rare categories within the dataset. If, however, the segment definition does not include any rare categories, a second CTGAN model 500 trained on non-rare categories data is employed for sampling. This ensures that profiles generated for segments without rare categories accurately represent the distribution and characteristics of the majority categories.

By employing CTGAN 500 for conditional profile generation, the pipeline ensures that synthetic profiles are generated based on the specified segment definition characteristics, thereby facilitating accurate simulation and analysis of user behaviors and responses. In the context of CTGANs, conditional generation refers to the ability to generate synthetic data conditioned on input conditions, such as specific segment definitions or contexts. These input conditions can include categorical variables, numerical features, or any other relevant information that influences the characteristics of the generated data. These input conditions can include categorical variables, numerical features, or any other relevant information that influences the characteristics of the generated data. For example, in user profile generation, the segment definition in 503 could be demographic information like age group, gender, or location. By conditioning the generation process on specific input conditions, CTGANs can produce synthetic user profiles that conforms to the desired conditions specified by the user.

The synthetic user profile generator 505 is generally responsible for iteratively generating synthetic user profiles until a user profile is selected for the output by meeting one or more certain thresholds set by the user profile discriminator 507. The synthetic user profile generator 505 iteratively and incrementally generates synthetic user profiles until it fools (e.g., is within a threshold set by) the user profile discriminator 507, at which point the corresponding synthetic user profile is outputted.

In generating these synthetic user profiles, the synthetic user profile generator 505 learns the distribution of classes or clusters that represent specific user profiles of the dataset in 503. For example, the synthetic user profile generator 505 is trained, at different times, on rare and non-rare categories, where the user profiles are labeled as “fake” (1) or “real” (0). A “real” user profile represents actual data (e.g., age, gender, clicks, conversations, etc.) of a real person that actually exists or has existed and has engaged on an actual/real platform (e.g., an electronic marketplace). For example, the synthetic user profile generator 505 can then learn features associated with each of these labels so that it knows how to iteratively apply data indicative of particular synthetic user profiles (so that the synthetic user profiles do not appear fake in images).

In some embodiments, the synthetic user profile generator 505 is built by selecting an input Z, which may be a random number between 0 and 1 (e.g., 0.7). This input may be a feature vector that comes from a fixed distribution. Z may then be multiplied by each learned weight, which indicates the learned feature (e.g., age, click quantity, etc.) for the particular synthetic user profile and/or whether or not the particular synthetic user profile is real. In some embodiments, the synthetic user profile generator 505 can incrementally, for example, adjust individual tabular values (along with sigmoid) until these values fool the user profile discriminator 507 by generating values (e.g., click rates views, age, etc.) within an acceptable threshold or range that the discriminator 707 is aware of. At a high level, what this means is that a well-trained generator 505 will always generate profiles that appear real but may do so with varying degrees of values.

The user profile discriminator 507 is generally responsible for determining, predicting, or estimating whether user profiles generated by the generator 505 are real or fake. In some embodiments, the discriminator 509 adds values representing individual values indicative of real user profiles and subtracts values indicative of fake user profiles. Various embodiments can then set any suitable threshold value to indicate whether a certain user profile is real or not. For example, if the summed values are greater than or equal to 1, the user profile is real relative to values less than 1, which may mean that user profiles are fake. In neural networks, and in some embodiments, each neural network node represents a particular tabular attribute (e.g., age, clicks, etc.) and its value. In this way, and using the example above, all the values can be multiplied or added by plus 1 (e.g., user profiles are real) or −1 (e.g., user profiles are not real) for a final aggregation score. Some embodiments use a sigmoid function (a function that converts high numbers to numbers close to 1 and low numbers to numbers close to 0) to get a sigmoid of the output, which represents the probability that a user profile is real or fake.

Various embodiments train the CTGAN 500 to get the best possible weights (e.g., values that closely resemble real user profiles). This can be done via an error function (e.g., log loss or cross entropy loss), which a mechanism to tell the CTGAN 500 how it is performing. If the error is large, the CTGAN 500 is not performing well and therefore performs more training epochs until it improves. In some embodiments, training occurs via backpropagation by calculating the prediction and then error of that prediction. Then embodiments can take the derivative of the error based on the weights using, for example, the chain rule. This tells the model the quantity or magnitude each weight should be adjusted in order to best decrease the error using gradient descent. In response to this process, the generator 505 and the discriminator 507 are trained. Suitable error functions can be placed in suitable locations. At a first training forward pass, the weights can be defined as random numbers. Then Z can be generated, which serves as an input to the generator 505. As embodiments perform the first forward pass on the generator 505, the output user profile may likely be fake or not indicative of a real user profile since the weights are random. Various embodiments pass this user profile through the discriminator 507. The discriminator 507 outputs a probability to define the correct error functions. For example, if the label of a user profile is 0 (e.g., a fake user profile), but the discriminator 507 makes a prediction 0.54, this means that the discriminator 507 is not highly confident that the user profile is real. Responsively, an error loss function (e.g., log loss) can be applied to get the prediction closer to 0. However, the generator 506's goal is to use the loss of the discriminator 507 as an objective function to modify parameters or weights of its model in order to maximize the loss of the discriminator 507. Using the example, above, the goal is to get the discriminator 507 to output a 1 instead of a 0. In this way, the loss from the discriminator 507 is passed to the generator 505 so that the generator 505 can maximize the loss (or get an incorrect prediction) of the discriminators. In some embodiments, the error loss function of the discriminator 507 is: E=−ln(1−D(x)), where D is the output of prediction of the discriminator 507. In some embodiments, the error loss function of the generator 505 is E=−ln (D(G(z))), where G is the output or prediction (i.e., the user profile) of the generator 505.

The derivatives of these two error loss functions can help the CTGAN 500 update the weights of the generator 505 and the discriminator 507 in order to improve a particular prediction. Accordingly, the tension or adversarial nature between these components adjusts weights in the respective models, such that there is no collision. This process can be repeated many times during training. After various iterations or epochs, the generator 505 will be trained to generate synthetic user profiles that closely resemble real user profiles.

In some embodiments, at runtime or when the CTGAN 500 is deployed after training, the generator 505 generates synthetic user profiles and because it has been trained with the correct loss, it outputs user profiles in a manner that looks realistic. This is because it generates values inside an acceptable threshold determined by the discriminator 507.

FIG. 6 depicts a diagram of an example neural network 605 that is trained to generate one or more touchpoint specific user responses, according to some embodiments. In some embodiments the neural network 605 represents or includes the campaign journey simulation component 112 of FIG. 1 and/or the journey simulator model(s)/layer(s) 214 of FIG. 2. In some embodiments, the neural network 605 represents any suitable model functionality, such as supervised learning (e.g., using logistic regression, using back propagation neural networks, using random forests, decision trees, etc.), unsupervised learning (e.g., using an Apriori algorithm, using K-means clustering), semi-supervised learning, reinforcement learning (e.g., using a Q-learning algorithm, using temporal difference learning), a regression algorithm (e.g., ordinary least squares, logistic regression, stepwise regression, multivariate adaptive regression splines, locally estimated scatterplot smoothing, etc.), an instance-based method (e.g., k-nearest neighbor, learning vector quantization, self-organizing map, etc.), a regularization method (e.g., ridge regression, least absolute shrinkage and selection operator, elastic net, etc.), a decision tree learning method (e.g., classification and regression tree, iterative dichotomiser 3, C4.5, chi-squared automatic interaction detection, decision stump, random forest, multivariate adaptive regression splines, gradient boosting machines, etc.), a Bayesian method (e.g., naïve Bayes, averaged one-dependence estimators, Bayesian belief network, etc.), a kernel method (e.g., a support vector machine, a radial basis function, a linear discriminate analysis, etc.), a clustering method (e.g., k-means clustering, expectation maximization, etc.), an associated rule learning algorithm (e.g., an Apriori algorithm, an Eclat algorithm, etc.), an artificial neural network model (e.g., a Perceptron method, a back-propagation method, a Hopfield network method, a self-organizing map method, a learning vector quantization method, etc.), a deep learning algorithm (e.g., a restricted Boltzmann machine, a deep belief network method, a convolution network method, a stacked auto-encoder method, etc.), a dimensionality reduction method (e.g., principal component analysis, partial lest squares regression, Sammon mapping, multidimensional scaling, projection pursuit, etc.), an ensemble method (e.g., boosting, bootstrapped aggregation, AdaBoost, stacked generalization, gradient boosting machine method, random forest method, etc.), and/or any suitable form of machine learning algorithm.

The neural network 605 is modeled as a data flow graph (DFG), where each node (e.g., 621) in the DFG is an operator with an input and output tensor, such as 620 and 622. A “tensor” (e.g., a vector) is a data structure that contains values representing the input, output, and/or transformations processed by the operator. Each edge of the DFG depicts the dependency between the operators. Neural network 605 includes an input layer, an output layer and one or more hidden layers. An Input layer is the first layer of the neural network 605. The input layer receives pre-processed (e.g., via the pre-processing 604 or 616) input data represented by 603 and 615. The Output layer (e.g., a classification layer) is the last layer of neural network 605. The output layer generates touch point user response predictions, which is represented by the inference and predictions 609 and 607. Neural network 605 may include any number of hidden layers. Hidden layers are intermediate layers in neural network 605 that perform various operations.

Each node in FIG. 6, such as node 621, is associated with or includes an activation tensor, such as input tensor 620, output tensor 622, and/or intermediate tensors. An “activation tensor” is a tensor that is an input, intermediate, and/or output to at least one neural network layer (e.g., as modeled going from left to right), as illustrated by the flow of data from input tensor 620 to output tensor 622. This is different than a weight tensor, such as 624, where weight tensors are modeled as flowing upward (not being actual inputs or outputs). In other words activation tensors represent some form of the neural network inputs 603 and 615. For example, the input tensor 620 or node 621 can represent specific data points, such as age, click amount range, or location, whereas a weight tensor represents the weight values indicating node activation/inhibition values indicating significance of the particular data point for the overall prediction at 609 or 607.

Each node in the network 605 may also be associated with or include and/or a weight tensor (e.g., 624), which include weight values. A “weight” in the context of machine learning may represent the importance or significance of a feature or feature value for prediction. For example, each feature (e.g., age, clicks, location,) may be associated with an integer or other real number where the higher the real number, the more significant the feature is for its prediction. In some aspects, a weight in a neural network represents the strength of a connection between nodes or neurons from one layer (an input) to the next layer (a hidden or output layer). A weight of 0 may mean that the input (e.g., the input tensor 620) will not change the output (e.g., the output tensor 622), whereas a weight higher than 0 changes the output. The higher the value of the input or the closer the value is to 1, the more the output will change or increase. Likewise, there can be negative weights. Negative weights may proportionately reduce the value of the output. For instance, the more the value of the input increases, the more the value of the output decreases. Negative weights may contribute to negative scores. For example, a particular touchpoint order may be highly correlated with a specific future touchpoint user response (a variable of interest) and so neural network layers or nodes representing the touchpoints may be weighted higher so that that this data is activated or taken into account when making a final prediction score.

Each node of the neural network 605 may additionally perform a function using the activation tensors and weight tensors, such as activation functions, matrix multiplication, normalization, or the like. In some examples, the nodes in the neural network 605 are fully connected or partially connected. Continuing with FIG. 6, each node may process an input in 603 and 615 (or portion thereof) using activation tensors and weight tensors. In some examples, in response to receiving the deployment input(s) 603 and the training data input(s) 315, the neural network 605 first performs pre-processing 604 or 616, such as encoding or converting such input into machine-readable indicia representing the entire input (e.g., a tensor representing all of the deployment input(s) 603). Responsively, the node may then receive an input tensor, which may, for example, represent whether a feature (e.g., a specific touchpoint in the journey map, age or click rang) are present in the input. In some examples, the input tensor is an N-dimensional tensor, where N can be greater than or equal to one. In some examples, an input tensor 620 represents the input data of neural network 605 if the node is in the input layer. In some examples, the input tensor 620 is also the output of another node in the preceding layer. In some examples after a node, such as the node 621, performs an operation using the input tensor 620, it generates an output tensor 622, which is then passed to the other neurons in the hidden layer and/or output layer. The output tensor 622 represents the output processed by the node 621. For example, the output tensor 622 may be a matrix representing the product of matrix multiplication or a matrix indicating whether particular touchpoints were present in a journey map. In various aspects, the output tensor 622 represents an input of another node in the succeeding layer (i.e., the output layer).

In some examples, node 621 applies a weight tensor 624 to the input tensor 620 via a linear operation (e.g., matrix multiplication, addition, scaling, biasing, or convolution). All other nodes in the neural network may perform identical functionality. In some examples, the result of the linear operation is processed by a non-linear activation, such as a step function, a sigmoid function, a hyperbolic tangent function (tan h), and rectified linear unit functions (ReLU) or the like. The result of the activation or other operation is an output tensor 622 that is sent to a subsequent connected node that is in the next layer of neural network 605. The subsequent node uses the output tensor 622 as the input activation tensor to another node.

Each of the functions in the neural network 605 may be associated with different coefficients (e.g., weights and kernel coefficients) that are adjustable during training. For example, after preprocessing 616 (e.g., normalization, feature scaling and extraction) in various aspects, the neural network 605 is trained using a data set of the preprocessed training data inputs 615 in order to make acceptable loss training predictions at the appropriate weights to set the weight tensors. This will help later at deployment time to make a correct inference 609. In some aspects, learning or training includes minimizing a loss function between the target variable (for example, a correct prediction of a user response to a touchpoint) and the actual predicted variable (for example, an incorrect prediction of a user response to a touchpoint). Based on the loss determined by a loss function (for example, Mean Squared Error Loss (MSEL), cross-entropy loss, etc.), the loss function learns to reduce the error in prediction over multiple epochs or training sessions so that the neural network 605 learns which features and weights are indicative of the correct inferences, given the inputs. Accordingly, it is desirable to arrive as close to 100% confidence in a particular classification or inference as much as possible so as to reduce the prediction error.

Subsequent to a first round/epoch of training, the neural network 605 makes predictions with a particular weight value, which may or may not be at acceptable loss function levels. For example, the neural network 605 may process the pre-processed additional training data inputs 615 a second time to make another pass of predictions. This process may then be repeated over multiple iterations or epochs until the weight values in the weight tensors are learned for optimal predicted values and/or the loss function reduces the error in prediction to acceptable levels of confidence.

Continuing with FIG. 6, in some examples, the neural network 605 is trained in a supervised manner using annotations or labels. For example, in some examples, training includes (or is preceded by) annotating/labeling training data 615 so that the neural network 605 learns associations between the features or weights and corresponding labels, which is used to change the weights/neural node connections for future predictions. For example, different touchpoints (or touchpoint journeys) in the real user profile data can be labeled with real touchpoint specific user responses (e.g., touchpoint-response pairs), for both rare and non-rare categories. For example, given a real touchpoint journey, where a user was presented with touchpoint A and then B, each of these touchpoints are labeled with corresponding labels indicating the specific user response, such as “clicked” and “no click.” Subject matter experts, programming logic, or other users may label such touchpoints with responses, which indicates how users have historically engaged with responses.

Additionally or alternatively, such labels may be indicative of touchpoint chains (e.g., a touchpoint-to-touchpoint pair), which indicates the order that touchpoints are ordered in journey maps (e.g., given a first touchpoint, a second touchpoint follows the first touchpoint). In this way, the neural network 305 can learn which weights or features are indicative of a specific user response and/or touchpoint given another particular touchpoint. As such, the neural network 605 accordingly adjusts the weights (the weight tensors) or deactivates nodes such that certain nodes corresponding particular performance values, parts, printer/material attributes, variables of interest, working conditions, or performance properties are activated and other nodes corresponding to other performance values, parts, printer/material attribute, variables of interest, working conditions, or performance properties are inhibited to make geometry modifications. In some embodiments, the “real user profile data” indicated in the training data input(s) 615 includes features and outcomes—both sets (e.g., input-output pairs, such as user attribute (e.g., age, country, click data)—user response pairs).

Subsequent to the neural network 605 training, the neural network 605 (for example, in a deployed state) receives the pre-processed deployment input(s) 603. When a machine learning model is deployed, it has been trained, tested, and packaged so that it can process data it has never processed. Responsively, in some aspects, the deployment input(s) 603 (i.e., synthetic user profile(s), journey map(s), and/or prior predicted user responses/touchpoints) are fed to the neural network 605, which then uses the same weight tensors (e.g., 624) that were learned via training so that the neural network 605 can produce the correct inference predictions 609. For example, the input tensor 620 can include new values (e.g., segment definition and user click range) which is then multiplied or otherwise combined with the weight tensor 624, representing the same weight values learned at training, in order to make the inference prediction(s) 609. “Prior predicted user responses/touchpoints” as illustrated in the input(s) 603 refer to inference prediction(s) made prior to the inference 609, which may be affected by prior inferences. For example, prior to the inference 609, the neural network 605 may predict that a user will respond to an email touchpoint by not clicking the email message. Responsively, at inference 609, the neural network 605 predicts that the next touchpoint (and/or response to such touchpoint) should be an ad presented via SMS based on the training data indicating that the highest conversion rate for someone that did not engage with an email is when a follow-up touchpoint was an SMS ad.

In some embodiments, at inference time (609), various embodiments map the deployment input(s) 603 as containing rare and/or non-rare categories (e.g., depending on whether click values exceed a threshold as described with respect to FIG. 4). Various embodiments then responsively call the neural network that has been trained on rare or non-rare categories based on whether the data included in the deployment input(s) is rare or non-rare. Similarly, some embodiments additionally or alternatively map the deployment input(s) 603 to the node type specific response model based on what is in the journey map (or other parameters the user issued). For example, some embodiments use natural language processing to map (e.g., via WORD2VEC) journey parameters, such as “present email; then present ad,” to a specific email response model to predict email click responses and a second specific add response model to predict add click responses, as described, for example, with respect to the journey simulator model(s)/layer(s) 214 of FIG. 2.

FIG. 7 is a screenshot 700 illustrating a simulated campaign journey and estimated user interaction statistics, according to some embodiments. In some embodiments, the screenshot 700 represents the output of the campaign journey simulation component 112 and presentation component 120 of FIG. 1. For example, the screenshot 700 may represent a user interface and what a user sees upon a request to simulate a campaign journey.

The simulated journey of the screenshot 700 includes frames 702, 704, 706, and 708 representing different stages and user interaction statistics of the simulated campaign journey under “condition 1” (i.e., “Guests who live in New York and use browser Safari”). A “condition” as described herein means the same thing and/or is interchangeable as a “segment definition” (e.g., segment definition 206) as described herein. The screenshot 700 additionally includes a set of corresponding fields 710 that illustrate additional user interaction statistics when there is no condition presented. Frame 702 represents a synthetic user profile (e.g., as generated by the synthetic profile generator 108 of FIG. 1) of “Regina” (a synthetic user) with “condition 1” (e.g., as represented by the condition(s) 511 and/or segment definition 206). Frame 702 illustrates that 1000 synthetic user profiles/users (including “Regina”) qualified under condition 1. That is, there is 1000 synthetic user profiles/users who live in New York and use a Safari web browser. The corresponding field 710 also illustrates that embodiments will compute user interaction statistics for 1000 other user profiles/users that do not quality for condition 1.

Frame 704 represents a particular touchpoint provided by a marketing platform and received by the “Regina” user (and the 999 other users). Such touchpoint is representative of a promotional message about an active promotion via email. Frame 704 also includes a click rate (i.e., estimated click probability) (0.056), which indicates a prediction of the amount/proportion of the 1000 users will click on the promotional message and/or the likelihood that Regina will click on the promotional message. In some aspects, the click rate of 0.056 indicates that only 5% of the 1000 users clicked on the promotional message. For such response estimation, any type or quantity of models can be used to compute this—from standard statistical models to neural networks and SVMs and decision trees, or the like. This is has the technical effect of flexibility since anyone utilizing the model can plug in their favorite model. Frame 704 also includes a confidence score (e.g., confidence bounds or interval) of plus or minus 0.007. This confidence interval provides information about the uncertainty associated with the estimate. Specifically, it suggests that embodiments are 95% confident that the true email click rate falls within the range of 0.049 to 0.063 (0.056±0.007). This means that if the same study was conducted many times and embodiments compute the confidence interval for each study, it would be expected that the true click rate to be within the interval for approximately 95% of the studies. The width of the confidence interval (in this case, 0.014) reflects the precision of the estimate. A narrower interval indicates a more precise estimate, while a wider interval indicates greater uncertainty or variability in the data.

Various embodiments predict/calculate such confidence intervals in any suitable manner. For example, first, the model (e.g., neural network 605) predicts the mean user response rate for each touchpoint. This mean response rate represents the average probability of a user responding to a particular touchpoint, such as clicking on an email or making a purchase. Next, the model uses bootstrap sampling to generate multiple samples of simulated user responses based on the predicted mean user response rates. Bootstrap sampling involves randomly sampling the observed data with replacement to create simulated datasets that reflect the variability in the original data. The model then simulates user responses for each touchpoint using the generated samples. By simulating responses multiple times, the model captures the uncertainty in the response rates and allows for the estimation of confidence intervals. Finally, the model calculates confidence intervals based on the simulated user responses. In some embodiments, the confidence intervals are calculated using percentiles of the simulated response distribution. For example, a 95% confidence interval may be calculated as the range between the 2.5th and 97.5th percentiles of the simulated response distribution. By following this process, various embodiments predict confidence intervals for various performance metrics, such as click-through rates or conversion rates, allowing senders to quantify the uncertainty associated with their predictions and make more informed decisions.

The corresponding field 712 indicates that for the 1000 users that do not meet condition 1, the email click rate is 0.0094 and the estimated confidence level is 0.002 (each of which is significantly lower than when the user qualifies under condition 1). Frame 706 indicates the predicted/estimate/simulated user response—that user Regina did not engage with the promotional message. The frame 706 also indicates that now only 944 synthetic user profiles/users qualify, meaning that it was simulated or predicted that 944 users (of the original 1000 users) did not click on the promotional message and now qualify for the next touchpoint indicated in the frame 708. In some embodiments, frame 706 (or indicating which users did not respond/engage) may be part of the journey map because the sender may be interested to see what to do after a user has decided not to respond to an original touchpoint. The corresponding field 714 indicates that 990 users (who do not meet condition 1) qualified to receive the reminder message in frame 708, meaning that during simulation, 990 of the 1000 users (who do not meet condition 1) failed to engage the promotional message at frame 704.

The frame 708 illustrates that Regina and the other qualified 944 users receive a reminder message—i.e., an ad. The frame 708 further illustrates that the ad click rate is simulated to be 0.004, meaning that the simulated indicates that only 0.4% of the 944 users clicked on the reminder message/ad, with a 0.004 confidence score. The corresponding field 716 indicates that for 944 other users that did not qualify for the reminder message in 708 and/or who do not meet condition 1, they had an ad click rate of 0.008 and a corresponding confidence score of 0.005.

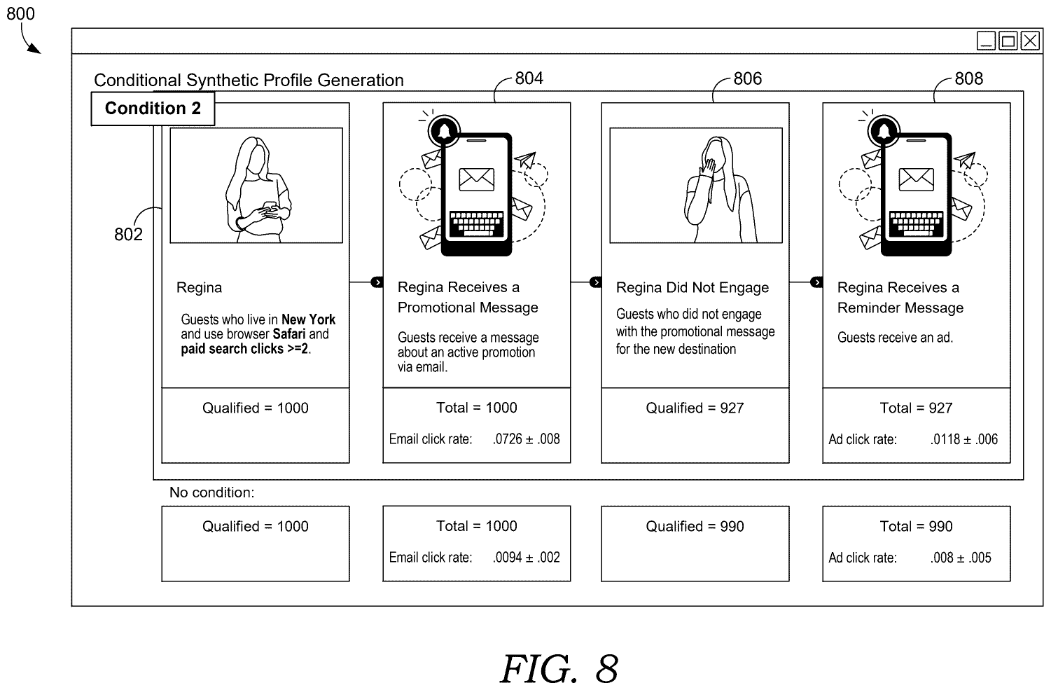

FIG. 8 is a screenshot 800 illustrating a slightly modified simulated campaign journey relative to the simulated campaign journey of FIG. 7 and estimated user interaction statistics, according to some embodiments. In some embodiments, the screenshot 800 represents the output of the campaign journey simulation component 112 and presentation component 120 of FIG. 1.

FIG. 8 specifically illustrates that, compared to FIG. 7, a user (or automated process) has provided an additional condition 2 or segment definition of “paid search clicks >=2,” as illustrated in frame 802, representing a modified synthetic user profile relative to the synthetic user profile indicated in frame 702 of FIG. 7. Specifically, such new condition 2 in the frame 802 indicates that the simulation or prediction should consider scenarios where the number of paid search clicks is greater than or equal to 2. This condition 2 could be part of defining a segment or subset of users within the dataset who have interacted with a paid search ad at least twice. By setting this condition, the simulation algorithm focuses on users who have demonstrated a higher level of engagement with paid search ads, which may be relevant for certain marketing strategies or analyses. For example, in a campaign journey simulation, this condition might be used to segment users who are more likely to convert after multiple interactions with paid search ads, allowing senders, such as marketers, to tailor their strategies accordingly.

As illustrated in frame 804, the simulated email click rate is 0.0726 (with a confidence score of 0.008), which is higher than the corresponding simulated click rate (0.056) indicated in frame 704 of FIG. 7, which indicates that the new “condition 2” is associated with a higher likelihood of a user engaging (e.g., clicking) with the promotional message. This is further indicated in the frame 806, where only 927 users qualified to receive the reminder message in frame 808 (i.e., only 927 users did not engage with the promotional message). This is a smaller number relative to corresponding frame 706 of FIG. 7, where 944 users qualified to receive the reminder message. Accordingly, comparing FIG. 7 to FIG. 8, FIG. 7 illustrates that the estimates of Email Click and Ad Click differ appreciably across the two conditions (condition 1 and condition 2). This illustrates the sensitivity of the modeling approach to two different conditional profile generations.

### Example Flow Diagrams

FIG. 9 is a flow diagram of an example process 900 for training one or more node specific response models, according to some embodiments. The process 900 (and/or any of the functionality described herein, such as process 1000) may be performed by processing logic that comprises hardware (e.g., circuitry, dedicated logic, programmable logic, microcode, etc.), software (e.g., instructions run on a processor to perform hardware simulation), firmware, or a combination thereof. Although particular blocks described in this disclosure are referenced in a particular order at a particular quantity, it is understood that any block may occur substantially parallel with or before or after any other block. Further, more (or fewer) blocks may exist than illustrated. Added blocks may include blocks that embody any functionality described herein (e.g., as described with respect to FIG. 1 through FIG. 11). The computer-implemented method, the system (that includes at least one computing device having at least one processor and at least one computer readable storage medium), and/or the computer readable medium as described herein may perform or be caused to perform the process 900 or any other functionality described herein.

Per block 902, some embodiments receive input parameters, which include profile data and mapping of rare and non-rare categories. The “profile data” refers to the dataset containing information about real users, such as their demographic details, past behaviors (e.g., clicks, purchase history, etc.), preferences, and any other relevant attributes that can be used to characterize them. The “mapping to rare and non-rare categories” involves categorizing certain attributes or features in the profile data as either “rare” or “non-rare,” as described, for example with respect to FIG. 4. This categorization helps in identifying features that occur infrequently or are less represented in the dataset compared to others. For example, if embodiments are analyzing customer data for an e-commerce platform, attributes like “premium membership status” or “frequent purchaser” might be considered non-rare, as they are relatively common among users. On the other hand, attributes like “big-ticket item buyer” or “international shopper” might be considered rare, as they apply to a smaller subset of users.

Per block 904, some embodiments then attach input parameters to respective nodes corresponding to touchpoints. Block 904 is built on the assumption that a campaign journey is represented as a network graph (e.g., a Directed Acyclic Graph (DAG)). By representing the campaign journey as a computational graph with nodes and edges, the algorithm can simulate user behavior and predict campaign outcomes by traversing the graph based on user interactions and response probabilities. This approach enables the modeling of complex marketing scenarios and facilitates the optimization of campaign strategies for better engagement and conversion.

Each “node” in the graph represents a specific touchpoint, response, and/or stage within the campaign journey. For example, nodes could represent different marketing channels or stages in a campaign journey, such as email, social media, website visit, etc. Edges represent the connections or transitions between nodes in the campaign journey. These transitions could indicate the probability of a user moving from one touchpoint to another based on historical data, user behavior patterns, or model predictions. In other words, edges define the flow of the user's journey through the campaign. Each node may have specific characteristics or attributes associated with it, such as the type of touchpoint, the content delivered, or the intended user action. These attributes could influence the probability of user responses at each stage of the journey. The strength or weight of the edges may represent the likelihood or probability of users transitioning between nodes. These probabilities could be derived from historical data or predicted by machine learning models trained on past user interactions.

With respect to block 904, consider the following example, there may exist an “Email Promotion Node,” where the input parameters include Subject line length, Number of product images included, and Discount percentage offered. With respect to the “attaching” in block 904, these input parameters are linked or associated to the email promotion node by defining how they influence user engagement and click-through rates for the email campaign. For example, longer subject lines or higher discount percentages may lead to higher email open rates and click-through rates.

Per block 906, some embodiments call fit( ) to train one or more node specific response models. The string “fit( )” is a method/function used in machine learning libraries such as TensorFlow or scikit-learn to train a model on a given dataset. When fit( ) is called, the function instructs the model to adjust its internal parameters (weights and biases) based on the input data, so that it can make better predictions. During the training process, the model iteratively adjusts its parameters to minimize the difference between its predictions and the actual outcomes in the training data. This process continues for a certain number of iterations (epochs) until the model has learned to make accurate predictions.

In an illustrative example, consider an example of training a node type specific response model for an email campaign node in a marketing simulation system, as described herein. The node is “Email Campaign Node.” This node represents an email marketing campaign, where the goal is to predict whether a user will open the email and click on the links within it. The input parameters may include Subject Line Length, Discount Percentage, Time of Day, Day of Week, User Segment, and Previous User Interaction History. Historical data may include information about past email campaigns, including: Subject line length, Discount percentage, Time of day and day of week the email was sent, User segment targeted by the campaign, and User interaction history (whether the user opened the email and clicked on links). The training algorithm reads the historical data and assigns weights to each input parameter based on how strongly they influence user engagement and click-through rates. The model iteratively adjusts its parameters using optimization techniques such as gradient descent to minimize the difference between predicted and actual user responses. In some embodiments, for each email campaign node, a separate response model is trained using the fit( ) function. The input parameters are linked to the email campaign node by defining their influence on user engagement and click-through rates. For example, longer subject lines or higher discount percentages may lead to higher email open rates and click-through rates.

Per block 908, for each touchpoint of the campaign journey map, particular embodiments return edge probabilities on journey canvas touchpoint. Block 908 refers to the probabilities associated with each edge (or transition) between touchpoints on the journey canvas. These probabilities represent the likelihood of a user moving from one touchpoint to another in the simulated campaign journey (e.g., responding/engaging with each touchpoint along the campaign journey). After the simulation algorithm has processed the input parameters and generated synthetic user profiles, it uses the trained response model to predict the probabilities of user responses at each touchpoint. Each edge probability indicates the likelihood of a user transitioning from one touchpoint to another. These probabilities are calculated based on various factors, including user characteristics, campaign parameters, and historical data. In some embodiments, the “Journey Canvas” refers to the visualization or representation of the campaign journey (e.g., the screenshot 700 or 800 of FIG. 7 or FIG. 8), which includes all the touchpoints and the connections (edges) between them. It provides a comprehensive view of how users interact with the marketing campaign over time.

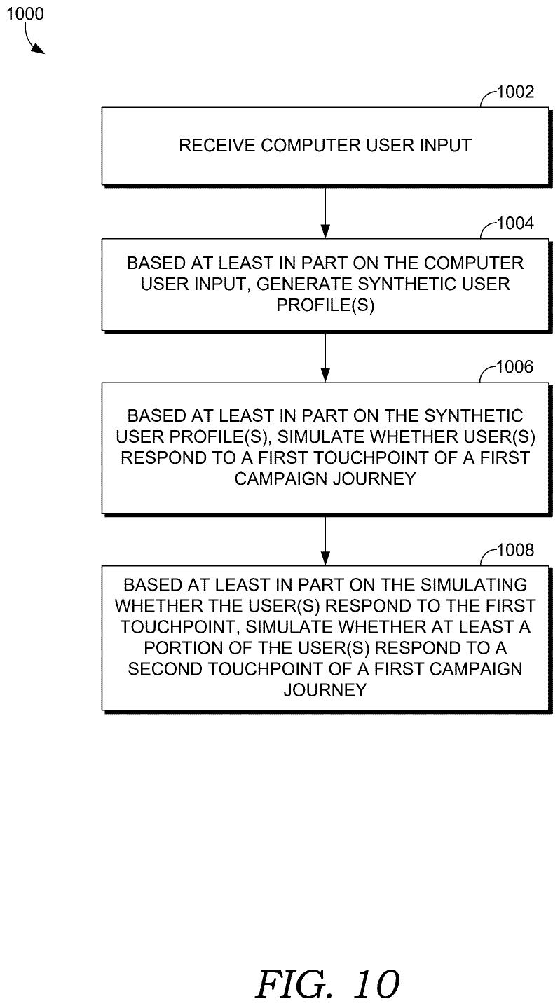

FIG. 10 is a flow diagram of an example process 1000 for simulating a first campaign journey, according to some embodiments. Per block 1002, some embodiments receive computer user input (e.g., mouse clicks, touch inputs, etc.). In some embodiments, the computer user input includes one or more journey parameters. A “journey parameter” is any information pertaining to a journey, such as a journey map (e.g., journey map 216) as described herein, and/or one or more constraints associated with a first journey. For example a constraint may be when a user specifies a particular touchpoint to be incorporated into the first simulation journey (e.g., state that the journey is to include a presentation of a specific ad). Alternatively, the user input may include an indication (e.g., a command or user interface selection) to deactivate the particular touchpoint (or any quantity of touchpoints) from the simulation of the first campaign journey. For example, a user may present a first journey map that specifies the specific types of touchpoints to be used and the order of the specific touchpoints. After a round of simulation, the user may deactivate one of multiple touchpoints by removing, for example, a node in a graph and/or replace such touchpoint with a different touchpoint. Alternatively or additionally, the user input includes a segment definition or condition representative of a target group of people. An example of a segment definition includes “condition 1” of FIG. 7—“Guests who live in New York and use Browser Safari.” In some embodiments, the user input additionally or alternatively includes historical user engagement/behavior data, such as the dynamic attributes described with respect to the dataset 202 of FIG. 2.

Per block 1004, based at least in part on the computer user input, some embodiments generate one or more synthetic user profiles. A “synthetic user profile” is a computer-generated user profile corresponding to a computer-generated user that does not necessarily reflect any real user that exists in the real world. Some embodiments alternatively “access” (e.g., from a data record in computer storage) one or more synthetic user profiles. It is understood that although block 1004 is described with respect to “synthetic” user profiles, any user profile may be generated or accessed. For example, a user profile may include a “real” user profile that corresponds to a real user that exists in the real world, such as a real user's name, age, browsing history, click history, etc.

In some embodiments, the generating of the one or more synthetic user profiles at block 1004 is based on using a Generative Adversarial Network (GAN) (e.g., a CTGAN) that is trained to distinguish between real user profiles and fake user profiles. Examples of this are described with respect to FIG. 4. There are other ways of generating a synthetic user profile. For example, the computer user input 102 may itself alone (without a model) represent the synthetic user profile. For example, the computer user input at block 1002 may state, “Jane Doe. New York City. Age 23.” These short snippets of text may represent a synthetic user profile in some embodiments. In some embodiments, a synthetic user profile includes or represents a segment definition or condition (e.g. “condition 1”) as described herein.

Per block 1006, based at least in part on the one or more synthetic user profiles, some embodiments simulate whether one or more users (e.g., synthetic users) respond to a first touchpoint of a first campaign journey. Examples of block 1006 are described in frame 706 of FIG. 7, which simulates that “Regina” (and the majority of users) did not engage with the promotional message. A “touchpoint” as described herein refers to content that is provided to a user within a journey. Examples of a touchpoint include, an email newsletter sign-up form on a website, a social media post promoting a product, a paid search ad displayed in search engine results, a product listing page on an e-commerce website, a push notification sent through a mobile app, a customer service chat interaction, a print advertisement in a magazine, a television commercial aired during a sports event, a booth at a trade show where attendees can learn about products, an email with a data object (e.g., a link) and/or an in-store display promoting a seasonal sale.

A “campaign journey,” in the context of marketing, refers to the sequence of touchpoints and/or user responses that a customer experiences as they engage with one or more touchpoints of the marketing campaign. It outlines the various steps or stages that a customer goes through from initial awareness of the campaign to taking desired actions, such as making a purchase or signing up for a service. A campaign journey typically includes different channels and mediums through which the campaign reaches the target audience, such as email, social media, website visits, and advertisements. Simulating whether a user “responds” to a particular touchpoint may include simulating whether a user clicks, selects, inputs, and/or otherwise engages with a touchpoint and/or purchases (e.g., real-world or virtual purchase) a product or service. A “journey” as described herein is not necessarily a campaign journey but any series of communications by any organization or other entity to its constituencies and/or responses by such constituencies. For example, a journey can include a government electronically communicating different policies (e.g., touchpoints) to citizens to make behavioral changes for social welfare; a financial services firm communicating to customers to change portfolio mix, or the like.

In some embodiments, the first touchpoint is indicative of or represents first content that is presented via a first channel (and the second touchpoint at block 1008 is indicative of second content that is presented via a second channel). “Channels” refer to the various mediums or platforms through which marketing messages or touchpoints are delivered to target audiences. Channels serve as the communication vehicles that enable businesses or organizations to reach and engage with their customers or prospects. Each channel may have unique characteristics, audience demographics, and engagement patterns. Examples of various channels include: email, social media, search engine, website, mobile app, Short Message Service (SMS) messaging (e.g., texts), or offline channels such as print media (newspapers, magazines), broadcast media (television, radio), direct mail, outdoor advertising (billboards, posters), and events (conferences, trade shows) are also used to reach target audiences. In some embodiments, simulating whether the one or more users responding to the first or second touchpoint includes at least one of: simulating a user responding by clicking a data object (e.g., a link) in an email, or simulating the user responding by clicking an ad.

The simulation at blocks 1006 and 1008 are included in a simulation for the first campaign journey. In some embodiments, the simulation of the first campaign journey further includes generating a first confidence score indicating a likelihood that the one or more users will respond the first touchpoint. Examples of such confidence score are illustrated in the frame 704, which computes a confidence of +/−0.0007 in relation to the simulated email click rate of 0.056. And based at least in part on the first confidence score, some embodiments perform any suitable action. For example, some embodiments simulate whether the one or more users respond to the first touchpoint of the first campaign journey (block 1006) and/or whether a portion of the one or more user respond to a second touchpoint of the first campaign journey (block 1008). For instance, as illustrated in FIG. 7, based on the email click rate being only 0.056 (representing only about 5% of all 1000 users), the first campaign simulation includes Regina not engaging with the promotional message, as indicated in frame 706 (which also influences other touchpoint responses, as illustrated in frame 708). In some of these embodiments, Regina or any other synthetic user may be predicted to respond/not respond based on some threshold being met or not met with respect to the user interaction statistics indicated in the frames. For example, if the email click rate indicated in frame 704 was over 50% or 0.50, embodiments may have simulated that Regina did respond to the promotional message.

Based at least in part on the confidence score (and/or the simulation of the first touchpoint), some embodiments additionally or alternatively predict that the second touch point of the campaign journey should follow the first touch point. In other words, some embodiments not only predict or simulate “responses” to touchpoints but the actual touchpoints that senders present. For example, a Reinforcement machine learning model may be trained to predict touchpoints based on journey maps that are labeled with user interaction statistics. The Reinforcement model may generate rewards for predicting next-in-line touchpoints that have the highest quantity of user responses (e.g., clicks or user purchases) and penalized for predicting touchpoints that have a lower quantity of user responses in real user profile data. The model may not only learn raw user interaction statistics associated with each touchpoint, but order dependencies available in journey maps of real users. For example, a user may be more likely to convert/purchase a product if presented with a first promotional message, and then a third promotional message, as opposed to being presented with only the third promotional message. Accordingly, the model may learn the first promotional message and third promotional message sequence/order by adjusting its weights not just based on the sheer amount of clicks for a given touchpoint, for example, but based on the order the touchpoint is presented in.

Some embodiments, additionally or alternatively generate a second confidence score indicating a likelihood that the one or more users will engage with the second touchpoint based on the first confidence score. Examples of this are described with respect to FIG. 7, where the +/−0.004 confidence score indicated in frame 708 is computed in part because of the first email click rate estimation of 0.056 and its associated confidence score of 0.007.

In some embodiments, the one or more synthetic user profiles include a plurality of synthetic user profiles associated with a plurality of users. In these embodiments, the simulation of the first campaign journey further includes determining a quantity or proportion of the plurality of users that have responded to the first touchpoint of the first campaign journey. Examples of this are described in FIG. 7, where frame 706 illustrates that 994 of 1000 users did not click on the promotional message, meaning that there was only a 0.056 email click rate, as indicated in frame 704.

Per block 1008, based at least in part on the simulating whether the one or more users respond to the first touchpoint, some embodiments simulate whether at least a portion of the one or more users respond to a second touchpoint of the first campaign journey. Examples of this are described with respect to frame 708 of FIG. 7, where it is simulated that Regina (and most of the other users) did not click on an ad (ad click rate −0.004). In some embodiments, the simulating at block 1006 is based on using a first machine learning model (e.g., XGBoost) and the simulating at block 1008 is based on using a second machine learning model (e.g., Logistic regression) that is distinct from the first machine learning model. Examples of these types of models are described with respect to the node type-specific response model that are employed to simulate user responses at each touchpoint. For example, the first machine learning model (e.g., neural network 605 of FIG. 6) may be an email click prediction model and the second machine learning model may be an ad click prediction model.

In some embodiments, the process 1000 further includes accessing a dataset (e.g., raw dataset 202) that includes a plurality of user engagements events between a plurality of users and one or more services. In some embodiments, such plurality of users refers to real users of real user profiles. User engagement events can include any suitable user input, such as one or more clicks, views, purchases, etc. Some embodiments then parse the dataset into a rare category and a non-rare category based on a quantity of an attribute value exceeding a threshold. Based on the parsing, some embodiments assign one or more attribute values of the one or more synthetic user profiles to the rare category or the non-rare category, where at least one of the generating of the one or more synthetic user profiles or the simulation of the first campaign journey is based on the assigning. Examples of this are described with respect to FIG. 4 and the preprocessing model(s)/layer(s) 204 where the raw dataset 202 is parsed into the binned/categorical data 208.

In some embodiments, the process 1000 includes generating one or more second synthetic user profiles, the one or more second synthetic user profiles being different than the one or more synthetic user profiles. Examples of this are described with respect to FIG. 8 where the “condition 2” indicated in the frame 802 is different than “condition 1” indicated in the corresponding frame 702. Based at least in part on the one or more second synthetic user profiles, some embodiments simulate whether one or more second users respond to the first touchpoint of the first campaign journey such that the simulation of whether the one or more second users respond to the first touch point of the first campaign journey is different relative to the simulation of whether the one or more users respond to the first touch point based on the one or more second synthetic user profiles being different than the one or more synthetic user profiles. Examples of this are described with respect to FIG. 8 relative to FIG. 7, where the same campaign journey is undertaken, but the user interaction statistics (e.g., the email click rate and the ad click rate) are different in FIG. 7 relative to FIG. 8 based on condition 2 being added to the synthetic user profile in FIG. 8.

### Exemplary Operating Environments

Turning now to FIG. 11, a schematic depiction is provided illustrating an example computing environment 1100 for recommending one or more color values for applying to an input image, in which some embodiments of the present invention may be employed. It should be understood that this and other arrangements described herein are set forth only as examples. Other arrangements and elements (e.g., machines, interfaces, functions, orders, groupings of functions, etc.) can be used in addition to or instead of those shown, and some elements may be omitted altogether. Further, many of the elements described herein are functional entities that may be implemented as discrete or distributed components or in conjunction with other components, and in any suitable combination and location. For example, there may be multiple servers 1110 that represent nodes in a cloud computing network. Various functions described herein as being performed by one or more entities may be carried out by hardware, firmware, and/or software. For instance, various functions may be carried out by a processor executing instructions stored in memory.

The environment 100 depicted in FIG. 11 includes a prediction server (“server”) 1110 that is in communication with the network 110. The environment 1100 further includes a client device (“client”) 1120 that is also in communication with the network 110. Among other things, the client 1120 can communicate with the server 1110 via the network 110, and generate for communication, to the server 1110, a request to make a detection, prediction, or classification of one or more instances of a document/image. The request can include, among other things, a request to perform video object segmentation. In various embodiments, the client 1120 is embodied in a computing device, which may be referred to herein as a client device or user device, such as described with respect to the computing device 12 of FIG. 12.

In some embodiments, each component FIG. 1 is included in the server 1110 or the client device 1120. Alternatively, in some embodiments, the components in FIG. 1 are distributed between the server 1110 and client device 1120.

The server 1110 can receive the request communicated from the client 1120, and can search for relevant data via any number of data repositories to which the server 1110 can access, whether remotely or locally. A data repository can include one or more local computing devices or remote computing devices, each accessible to the server 1110 directly or indirectly via network 110. In accordance with some embodiments described herein, a data repository can include any of one or more remote servers, any node (e.g., a computing device) in a distributed plurality of nodes, such as those typically maintaining a distributed ledger (e.g., block chain) network, or any remote server that is coupled to or in communication with any node in a distributed plurality of nodes. Any of the aforementioned data repositories can be associated with one of a plurality of data storage entities, which may or may not be associated with one another. As described herein, a data storage entity can include any entity (e.g., retailer, manufacturer, e-commerce platform, social media platform, web host) that stores data (e.g., names, demographic data, purchases, browsing history, location, addresses) associated with its customers, clients, sales, relationships, website visitors, or any other subject to which the entity is interested. It is contemplated that each data repository is generally associated with a different data storage entity, though some data storage entities may be associated with multiple data repositories and some data repositories may be associated with multiple data storage entities. In various embodiments, the server 1110 is embodied in a computing device, such as described with respect to the computing device 1200 of FIG. 12.

Having described embodiments of the present invention, an exemplary operating environment in which embodiments of the present invention may be implemented is described below in order to provide a general context for various aspects of the present invention. Referring initially to FIG. 12 in particular, an exemplary operating environment for implementing embodiments of the present invention is shown and designated generally as computing device 1200. Computing device 1000 is but one example of a suitable computing environment and is not intended to suggest any limitation as to the scope of use or functionality of the invention. Neither should the computing device 1000 be interpreted as having any dependency or requirement relating to any one or combination of components illustrated.

Looking now to FIG. 12, computing device 1200 includes a bus 10 that directly or indirectly couples the following devices: memory 12, one or more processors 14, one or more presentation components 16, input/output (I/O) ports 18, input/output components 20, and an illustrative power supply 22. Bus 10 represents what may be one or more buses (such as an address bus, data bus, or combination thereof). Although the various blocks of FIG. 12 are shown with lines for the sake of clarity, in reality, delineating various components is not so clear, and metaphorically, the lines would more accurately be gray and fuzzy. For example, one may consider a presentation component such as a display device to be an I/O component. Also, processors have memory. The inventor recognizes that such is the nature of the art, and reiterates that the diagram of FIG. 12 is merely illustrative of an exemplary computing device that can be used in connection with one or more embodiments of the present invention. Distinction is not made between such categories as “workstation,” “server,” “laptop,” “hand-held device,” etc., as all are contemplated within the scope of FIG. 12 and reference to “computing device.”

Computing device 1200 typically includes a variety of computer-readable media. Computer-readable media can be any available media that can be accessed by computing device 1200 and includes both volatile and nonvolatile media, and removable and non-removable media. By way of example, and not limitation, computer-readable media may comprise computer storage media and communication media. Computer storage media includes both volatile and nonvolatile, removable and non-removable media implemented in any method or technology for storage of information such as computer-readable instructions, data structures, program modules or other data. Computer storage media includes, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which can be used to store the desired information and which can be accessed by computing device 1200. Computer storage media does not comprise signals per se. Communication media typically embodies computer-readable instructions, data structures, program modules or other data in a modulated data signal such as a carrier wave or other transport mechanism and includes any information delivery media. The term “modulated data signal” means a signal that has one or more of its characteristics set or changed in such a manner as to encode information in the signal. By way of example, and not limitation, communication media includes wired media such as a wired network or direct-wired connection, and wireless media such as acoustic, RF, infrared and other wireless media. Combinations of any of the above should also be included within the scope of computer-readable media. In various embodiments, the computing device 1200 represents the client device 1120 and/or the server 1110 of FIG. 11.

Memory 12 includes computer-storage media in the form of volatile and/or nonvolatile memory. The memory may be removable, non-removable, or a combination thereof. Exemplary hardware devices include solid-state memory, hard drives, optical-disc drives, etc. Computing device 1200 includes one or more processors that read data from various entities such as memory 12 or I/O components 20. Presentation component(s) 16 present data indications to a user or other device. Exemplary presentation components include a display device, speaker, printing component, vibrating component, etc. In some embodiments, the memory includes program instructions that, when executed by one or more processors, cause the one or more processors to perform any functionality described herein, such as the process 1000 of FIG. 10, or any functionality described with respect to FIGS. 1 through 11.

I/O ports 18 allow computing device 1200 to be logically coupled to other devices including I/O components 20, some of which may be built in. Illustrative components include a microphone, joystick, gamepad, satellite dish, scanner, printer, wireless device, etc. The I/O components 20 may provide a natural user interface (NUI) that processes air gestures, voice, or other physiological inputs generated by a user. In some instances, inputs may be transmitted to an appropriate network element for further processing. An NUI may implement any combination of speech recognition, stylus recognition, facial recognition, biometric recognition, gesture recognition both on screen and adjacent to the screen, air gestures, head and eye tracking, and touch recognition (as described in more detail below) associated with a display of the computing device 1200. The computing device 1200 may be equipped with depth cameras, such as stereoscopic camera systems, infrared camera systems, RGB camera systems, touchscreen technology, and combinations of these, for gesture detection and recognition. Additionally, the computing device 1200 may be equipped with accelerometers or gyroscopes that enable detection of motion. The output of the accelerometers or gyroscopes may be provided to the display of the computing device 1200 to render immersive augmented reality or virtual reality.

As can be understood, embodiments of the present invention provide for, among other things, generating proof and attestation service notifications corresponding to a determined veracity of a claim. The present invention has been described in relation to particular embodiments, which are intended in all respects to be illustrative rather than restrictive. Alternative embodiments will become apparent to those of ordinary skill in the art to which the present invention pertains without departing from its scope.

From the foregoing, it will be seen that this invention is one well adapted to attain all the ends and objects set forth above, together with other advantages which are obvious and inherent to the system and method. It will be understood that certain features and sub combinations are of utility and may be employed without reference to other features and sub combinations. This is contemplated by and is within the scope of the claims.

The subject matter of the present invention is described with specificity herein to meet statutory requirements. However, the description itself is not intended to limit the scope of this patent. Rather, the inventors have contemplated that the claimed subject matter might also be embodied in other ways, to include different steps or combinations of steps similar to the ones described in this document, in conjunction with other present or future technologies. Moreover, although the terms “step” and/or “block” may be used herein to connote different elements of methods employed, the terms should not be interpreted as implying any particular order among or between various steps herein disclosed unless and except when the order of individual steps is explicitly described.

What is claimed is:

1. A system comprising:
at least one computer processor; and
one or more computer storage media storing computer-useable instructions that, when used by the at least one computer processor, cause the at least one computer processor to perform operations comprising:
receiving computer user input that includes at least one of: one or more journey parameters or a segment definition representative of a target group of people;
generating one or more synthetic user profiles;
based at least in part on the computer user input and the one or more synthetic user profiles, simulating whether one or more users respond to a first touchpoint of a first campaign journey; and
based at least in part on the simulating whether the one or more users respond to the first touchpoint, simulating whether at least a portion of the one or more users respond to a second touchpoint of the first campaign journey.

2. The system of claim 1, wherein the generating of the one or more synthetic user profiles is based on using a Generative Adversarial Network (GAN) that generates the one or more synthetic user profiles, the one or more synthetic user profiles mimic a distribution and characteristics of the target group of people.

3. The system of claim 1, wherein the user input further includes at least one of: specifying a particular touchpoint to be incorporated into the first simulation journey or an indication of deactivating the particular touchpoint from the simulation of the first campaign journey, and wherein the simulation of the first campaign journey is further based on the specifying or the indication.

4. The system of claim 1, wherein simulation of the first campaign journey further includes:
generating a first confidence score indicating a likelihood that the one or more users will respond the first touchpoint; and
based at least in part on the first confidence score, performing at least one of: simulating whether at least the portion of the one or more users respond to the second touchpoint of the first campaign journey, predicting that the second touch point of the campaign journey should follow the first touch point, or generating a second confidence score indicating a likelihood that the one or more users will engage with the second touchpoint.

5. The system of claim 1, wherein the one or more synthetic user profiles includes a plurality of synthetic user profiles associated with a plurality of users, and wherein the simulation of the first campaign journey further includes:
determining a quantity or proportion of the plurality of users that have responded to the first touchpoint of the first campaign journey.

6. The system of claim 1, wherein the simulating whether the one or more users respond to the first touchpoint of the first campaign journey is based on using a first machine learning model and the simulating whether at least a portion of the one or more users respond to the second touchpoint of the first campaign journey is based on using a second machine learning model that is distinct from the first machine learning model.

7. The system of claim 1, wherein the operations further comprising:
accessing a dataset that includes a plurality of user engagements events between a plurality of users and one or more services;
parsing the dataset into a rare category and a non-rare category based on a quantity of an attribute value exceeding a threshold; and
based on the parsing, assigning one or more attribute values of the one or more synthetic user profiles to the rare category or the non-rare category, wherein at least one of the generating of the one or more synthetic user profiles or the simulation of the first campaign journey is based on the assigning.

8. The system of claim 1, wherein the first touchpoint is indicative of first content that is presented via a first channel, and wherein the second touchpoint is indicative of second content that is presented via a second channel.

9. The system of claim 1, wherein the one or more users responding to the first or second touchpoint includes at least one of: a user responding by clicking a data object in an email, or the user responding by clicking an ad.

10. The system of claim 1, wherein the operations comprising:
generating one or more second synthetic user profiles, the one or more second synthetic user profiles being different than the one or more synthetic user profiles; and
based at least in part on the one or more second synthetic user profiles, simulating whether one or more second users respond to the first touchpoint of the first campaign journey, and wherein the simulation of whether the one or more second users respond to the first touch point of the first campaign journey is different relative to the simulation of whether the one or more users respond to the first touch point based on the one or more second synthetic user profiles being different than the one or more synthetic user profiles.

11. A computer-implemented method comprising:
accessing a user profile; and
based on the user profile, simulating a first journey, the simulation of the first journey includes:
generating a first set of one or more scores indicative of at least a likelihood that one or more users will respond to a first touchpoint of the first journey; and
based at least in part on the first set of one or more scores, generating a second set of one or more scores indicative of at least a likelihood that the one or more users will respond to a second touchpoint of the first journey.

12. The computer-implemented method of claim 11, wherein the user profile is one of a real user profile or a synthetic user profile, and wherein the synthetic user profile is generated based on incorporating one or more conditions and based on using a Generative Adversarial Network (GAN) that is trained to distinguish between real user profiles and fake user profiles.

13. The computer-implemented method of claim 11, further comprising:
receiving computer user input that includes at least one of: one or more journey parameters, a segment definition representative of a target group of people, specifying a particular touchpoint to be incorporated into the first simulation journey, or an indication of deactivating the particular touchpoint from the simulation of the first journey, and wherein the simulation of the first journey is further based on the computer user input.

14. The computer-implemented method of claim 11, wherein simulation of the first journey further includes:
based at least in part on the user profile, simulating whether one or more users respond to the first touchpoint of the first journey; and
based at least in part on the simulating whether the one or more users respond to the first touchpoint, simulating whether at least a portion of the one or more users respond to the second touchpoint of the first journey.

15. The computer-implemented method of claim 14, wherein the simulating whether one or more users respond to the first touchpoint of the first journey is based on using a first machine learning model and the simulating whether at least a portion of the one or more users respond to the second touchpoint of the first journey is based on using a second machine learning model that is distinct from the first machine learning model.

16. The computer-implemented method of claim 11, wherein the user profile is one of a plurality of user profiles associated with a plurality of users, and wherein the simulation of the first journey further includes:
determining a quantity or proportion of the plurality of users that have responded to the first touchpoint of the first journey.

17. The computer-implemented method of claim 11, further comprising:
accessing a dataset that includes a plurality of user engagements events between a plurality of users and one or more services;
parsing the dataset into a rare category and a non-rare category based on a quantity of an attribute value exceeding a threshold; and
based on the parsing, assigning one or more attribute values of the user profile to the rare category or the non-rare category, wherein at least one of generating the user profile or simulation of the first journey is based on the assigning.

18. The computer-implemented method of claim 11, wherein the first touchpoint is indicative of first content that is presented via a first channel, and wherein the second touchpoint is indicative of second content that is presented via a second channel.

19. A system comprising:
a synthetic profile generator means for generating a plurality of synthetic user profiles associated with a plurality of simulated users; and
based on the plurality of synthetic user profiles, a campaign journey simulation component means for simulating a first campaign journey, the simulation of the first campaign journey includes:
simulating whether each simulated user, of the plurality of simulated users, respond to a first touchpoint of the first campaign journey; and
based at least in part on the simulating whether each simulated user, of the plurality of simulated users, respond to the first touchpoint, simulating whether at least a portion of the plurality of simulated users respond to a second touchpoint of the first campaign journey, the second touchpoint being a different type than the first touchpoint.

20. The system of claim 19, wherein the campaign journey simulation component is further for:
receiving computer user input that includes at least one of: one or more journey parameters, a segment definition representative of a target group of people, specifying a particular touchpoint to be incorporated into the first simulation journey, or an indication of deactivating the particular touchpoint from the simulation of the first campaign journey, and wherein the simulation of the first campaign journey is further based on the computer user input.
